(19) United States
(12) Patent Application Publication
(10) Pub. No.: US 2014/0014928 A1
(43) Pub. Date: Jan. 16, 2014

(54) ORGANIC EL ELEMENT, RADIATION-SENSITIVE RESIN COMPOSITION, AND CURED FILM

(71) Applicant: JSR Corporation, Minato-ku (JP)

(72) Inventors: Yoshihisa OKUMURA, Tokyo (JP); Masashi Arai, Tokyo (JP)

(73) Assignee: JSR Corporation, Minato-ku (JP)

(21) Appl. No.: 13/937,828

(22) Filed: Jul. 9, 2013

(30) Foreign Application Priority Data
Jul. 12, 2012 (JP) 2012-156382
May 8, 2013 (JP) 2013-98706

(51) Int. Cl. H01L 51/52

(52) U.S. Cl. CPC H01L 51/5296
USPC 257/40; 524/190

(57) ABSTRACT

The organic EL display element is constituted by having a substrate, a TFT disposed on the substrate, a protective film covering the TFT, an anode disposed on the protective film, an organic luminescent layer disposed on the anode, a bank that defines an arranging area for the organic luminescent layer, and a cathode disposed on the organic luminescent layer. At least one of the protective film and bank is constituted as a cured film that is formed by using a radiation-sensitive resin composition containing a resin and a compound having a quinonediazide structure, contains a resin and at least one of a compound having a quinonediazide structure and a compound having an indenecarboxylic acid structure, and has an excellent patterning property.

### CROSS-REFERENCE TO THE RELATED APPLICATION

The entire disclosures of Japanese Patent Application No's. 2012-156382, filed on Jul. 12, 2012 and 2013-098706, filed on May 8, 2013 including specifications, claims, drawings, and summaries, on which the Convention priority of the present application is based, are incorporated herein in their entirety.

### FIELD OF THE INVENTION

This invention relates to an Organic EL (electroluminescence) Element, Radiation-sensitive resin composition and Cured film.

### BACKGROUND

Organic EL elements are elements utilizing electroluminescence by organic compounds, and are used as organic EL display elements, organic EL illumination lamps and the like.

For example, organic EL display elements are self-luminous display elements utilizing electroluminescence by organic compounds, which do not require backlights and enable image display with a wide vision angle and a high-speed response. Furthermore, they have excellent characteristics such as low electrical power consumption, thinness and lightness.

For these characteristics, the development of organic EL display elements and organic EL illumination lamps has actively proceeded in recent years.

Organic EL display elements, which are organic EL elements, each has a characteristic structure having an anode and a cathode, and an organic luminescent layer disposed between those two electrodes. The organic luminescent layer emits light by an electric field formed between the two electrodes, and the constitutional materials therefor are roughly classified into materials using low molecular weight materials and materials using polymeric materials.

Organic luminescent layers using low molecular weight materials are formed by dry processes using a vacuum deposition process and the like in many cases. On the other hand, organic luminescent layers using polymeric materials can be formed by, for example, applying a luminescent material composition containing an organic luminescent material and a solvent to each pixel of plural pixels that are possessed by a display element by using a technique such as an inkjet process, and drying the composition. In the case where an inkjet process is utilized, the utilization efficiency of the luminescent material composition to be applied can be significantly improved. Furthermore, an organic EL display element of an organic luminescent layer formed by using a polymeric material has characteristics that the organic EL display element can be driven at a relatively low voltage, consumes small electrical power, and easily accommodates screens that are getting larger.

In the case where an organic luminescent layer is formed by an application process such as an inkjet process, it is necessary to prevent intrusion of a luminescent material composition to adjacent pixels that emit lights of other colors.

In order to prevent the intrusion of the luminescent material composition to the adjacent pixels that emit lights of other colors, a technique including forming a division wall (hereinafter referred to as a bank), and adding dropwise a luminescent material composition containing an organic luminescent material to an area defined by this bank is known (for example, see JP 2006-004743 A and JP 2010-282899 A). The bank can be formed into, for example, a grid-like pattern by using a material such as a polyimide resin and an acrylic resin. By properly applying the luminescent material composition into the area defined by this bank, the intrusion of the luminescent material composition to the adjacent pixels that emit lights of other colors can be prevented.

FIG. 2 is a cross-sectional view schematically showing the structure of the major part of a conventional organic EL display element.

As shown in FIG. 2, a conventional active matrix-type organic EL display element 100 has, for example, a substrate 102 using non-alkali glass or the like, and plural pixels that are formed in a matrix pattern on the substrate, wherein each pixel has a thin film transistor (Thin Film Transistor: TFT) 103 disposed thereon as an active element. The TFT 103 is constituted by having a gate electrode 104, a gate insulating film 105, a semiconductor layer 106, a first source-drain electrode 107 and a second source-drain electrode 108 on the substrate 102.

Furthermore, a protective film 110 is disposed so as to cover the TFT 103 from the upper side to thereby protect the surface of the substrate on which the TFT 103 is formed. The protective film 110 is required to have a function to planarize the surface of the substrate on which the TFT 103 is formed. An anode 111 that forms a pixel electrode is disposed on this protective film 110. A through-hole 112 is formed on the protective film 110, and the anode 111 is connected to a second source-drain electrode 108 of the TFT 103 through the through-hole 112. The protective film 110 can be formed of a silicon oxide film (see JP 2008-15293 A).

A bank 113, which is a barrier wall, is formed above the TFT 103, and an organic luminescent layer 114 is disposed on an area defined by the bank 113. The bank 113 encompasses the surrounding of the organic luminescent layer 114 to thereby section the adjacent respective pixels with each other. Furthermore, a cathode 115 is formed so as to cover the organic luminescent layer 114 and to cover the bank 113 for sectioning the pixels. The cathode 115 is formed so as to commonly cover the plural pixels to thereby constitute a common electrode. A passivation film 116 is disposed on the cathode 115. The main surface on which the organic luminescent layer 114 is disposed of the thus-constituted substrate 102 is sealed by, for example, a sealing substrate 120 using non-alkali glass, through a sealing layer 117 by using a sealant (not depicted) that is applied in the vicinity of the outer periphery end part.

In the organic EL display element having the above-mentioned structure, the bank is disposed so as to define an area where an organic luminescent layer is to be formed. Therefore, the bank is required to sufficiently ensure an effective surface area of the organic luminescent layer, and to define the area where the organic luminescent layer is to be formed so that the shapes of the organic luminescent layers are uniform among the respective pixels. Therefore, it is necessary for the bank to have a controlled even shape. Specifically, the bank is required to have a narrow line width, to be even without variation, and thus to generate no backlash in the shape of the edge part.

Furthermore, a function to effect planarization is required and a function to form and dispose a through-hole having a desired shape is also required for a protective film for an organic EL display element. Namely, a protective film is required to attain a controlled shape and to have even through-holes. By attaining those, an organic EL display element can attain a connection of an anode and a TFT with high reliability, and can also increase effective luminescent areas in pixels.

Therefore, in an organic EL display element, excellent shape control is strongly demanded specifically in constitutional factors such as a bank and a protective film. Namely, in an organic EL element, excellent shape control is strongly demanded specifically in constitutional factors such as a bank and a protective film.

The present invention was made in view of the above-mentioned problems. Namely, the present invention aims at providing an organic EL element including a protective film having a desired shape. Furthermore, the present invention aims at providing an organic EL element including a bank having a desired shape.

Specifically, the present invention aims at providing an organic EL display element including constitutional elements having desired shapes such as a bank and a protective film having desired shapes.

Furthermore, the present invention aims at providing a radiation-sensitive resin composition used for forming a protective film having a desired shape for an organic EL element. Furthermore, the present invention aims at providing a radiation-sensitive resin composition used for forming a bank having a desired shape.

Specifically, the present invention aims at providing a radiation-sensitive resin composition used for forming a bank having a desired shape and a radiation-sensitive resin composition used for forming a protective film having a desired shape for an organic EL element.

Furthermore, the present invention aims at providing a cured film that forms a protective film having a desired shape and a cured film that forms a bank having a desired shape for an organic EL element.

Specifically, the present invention aims at providing a cured film that forms a bank having a desired shape and a cured film that forms a protective film having a desired shape for an organic EL display element.

### SUMMARY OF THE INVENTION

According to one aspect of the present invention, an organic EL element comprising a substrate, an active element disposed on the substrate, a protective film covering the active element, a first electrode disposed on the protective film, an organic luminescent layer disposed on the first electrode, and a second electrode disposed on the organic luminescent layer, wherein the protective film comprises a first resin, and at least one of a compound having a quinonediazide structure and a compound having an indenecarboxylic acid structure.

Further to this aspect of the present invention, an organic EL element, wherein the protective film has a through-hole, and the first electrode is configured to be connected to the active element through the through-hole.

Further to this aspect of the present invention, an organic EL element, wherein the first resin is formed of at least one kind selected from the group consisting of an acrylic resin having a carboxyl group, a polyimide resin, a polysiloxane and a novolak resin.

Further to this aspect of the present invention, an organic EL element, wherein the protective film contains an ultraviolet absorber.

Further to this aspect of the present invention, an organic EL element, wherein the ultraviolet absorber comprises one kind selected from a compound represented by the following general formula (1) and a compound represented by the following general formula (2):

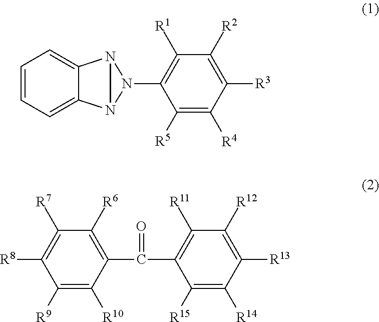

wherein in the formulas (1) and (2), R¹ to R¹⁵ each independently represents hydrogen, an alkyl group having 1 to 20 carbon atom(s), an alkoxy group having 1 to 20 carbon atom(s), a benzoyloxy group having 1 to 20 carbon atom(s) or a hydroxyl group.

Further to this aspect of the present invention, an organic EL element, which comprises a bank disposed on the active element and configured to define an arranging area for the organic luminescent layer.

Further to this aspect of the present invention, an organic EL element according to claim 6, wherein the bank comprises a second resin, and at least one of a compound having a quinonediazide structure and a compound having an indenecarboxylic acid structure.

Further to this aspect of the present invention, an organic EL element, wherein the second resin is formed of at least one kind selected from the group consisting of an acrylic resin having a carboxyl group, a polyimide resin, a polysiloxane and a novolak resin.

Further to this aspect of the present invention, an organic EL element according to claim 6, wherein the bank contains an ultraviolet absorber.

Further to this aspect of the present invention, an organic EL element, wherein the ultraviolet absorber comprises one kind selected from a compound represented by the following general formula (1) and a compound represented by the following general formula (2):

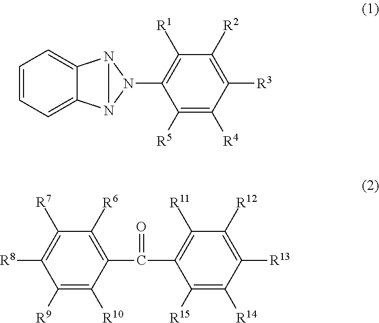

wherein in the formulas (1) and (2), R¹ to R¹⁵ each independently represents hydrogen, an alkyl group having 1 to 20 carbon atom(s), an alkoxy group having 1 to 20 carbon atom(s), a benzoyloxy group having 1 to 20 carbon atom(s) or a hydroxyl group.

Further to this aspect of the present invention, an organic EL element, wherein the active element is configured to have a semiconductor layer, and the semiconductor layer is configured by using silicon (Si).

Further to this aspect of the present invention, an organic EL element, wherein the active element is configured to have a semiconductor layer, and the semiconductor layer is formed by using an oxide configured to comprise at least one kind of indium (In), zinc (Zn) and tin (Sn).

Further to this aspect of the present invention, an organic EL element, wherein the semiconductor layer is formed by using at least one kind of zinc oxide (ZnO), indium gallium zinc oxide (IGZO), zinc tin oxide (ZTO) and indium zinc oxide (IZO).

According to another aspect of the present invention, an organic EL element comprising a substrate, an active element disposed on the substrate, a first electrode connected to the active element, an organic luminescent layer disposed on the first electrode, a bank disposed on the active element and configured to define an arranging area for the organic luminescent layer, and a second electrode disposed on the organic luminescent layer, wherein the bank comprises a resin, and at least one of a compound having a quinonediazide structure and a compound having an indenecarboxylic acid structure.

Further to this aspect of the present invention, an organic EL element, wherein the resin is formed of at least one kind selected from the group consisting of an acrylic resin having a carboxyl group, a polyimide resin, a polysiloxane and a novolak resin.

Further to this aspect of the present invention, an organic EL element, wherein the bank contains an ultraviolet absorber.

Further to this aspect of the present invention, an organic EL element, wherein the ultraviolet absorber comprises one kind selected from a compound represented by the following general formula (1) and a compound represented by the following general formula (2):

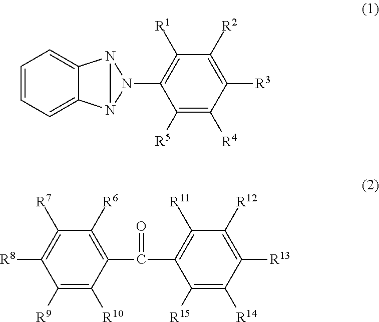

wherein in the formulas (1) and (2), R¹ to R¹⁵ each independently represents hydrogen, an alkyl group having 1 to 20 carbon atom(s), an alkoxy group having 1 to 20 carbon atom(s), a benzoyloxy group having 1 to 20 carbon atom(s) or a hydroxyl group.

Further to this aspect of the present invention, an organic EL element, which comprises a protective film covering the active element on the active element, and the first electrode is disposed on the protective film and configured to be connected to the active element through a through-hole disposed on the protective film.

Further to this aspect of the present invention, an organic EL element, wherein the active element is configured to have a semiconductor layer, and the semiconductor layer is configured by using silicon (Si).

Further to this aspect of the present invention, an organic EL element, wherein the active element is configured to have a semiconductor layer, and the semiconductor layer is formed by using an oxide configured to comprise at least one kind of indium (In), zinc (Zn) and tin (Sn).

Further to this aspect of the present invention, an organic EL element, wherein the semiconductor layer is formed by using at least one kind of zinc oxide (ZnO), indium gallium zinc oxide (IGZO), zinc tin oxide (ZTO) and indium zinc oxide (IZO).

Further to this aspect of the present invention, a radiation-sensitive resin composition for use in the formation of the protective film of the organic EL element, which comprises a resin and a compound having a quinonediazide structure.

Further to this aspect of the present invention, a radiation-sensitive resin composition for use in the formation of the bank of the organic EL element, which comprises a resin and a compound having a quinonediazide structure.

Further to this aspect of the present invention, a radiation-sensitive resin composition, wherein the organic EL element is configured by the active element having a semiconductor layer, and the semiconductor layer is formed by using an oxide constituted by containing at least one of indium (In), zinc (Zn) and tin (Sn).

Further to this aspect of the present invention, a cured film formed by using the radiation-sensitive resin composition, which constitutes a protective film for an organic EL element.

Further to this aspect of the present invention, a cured film formed by using the radiation-sensitive resin composition, which constitutes a bank for an organic EL element.

### BRIEF DESCRIPTION OF THE DRAWINGS

FIG. 1 is a cross-sectional view for schematically explaining the structure of the major part of the organic EL display element of the present exemplary embodiment.

FIG. 2 is a cross-sectional view schematically showing the structure of the major part of a conventional organic EL display element.

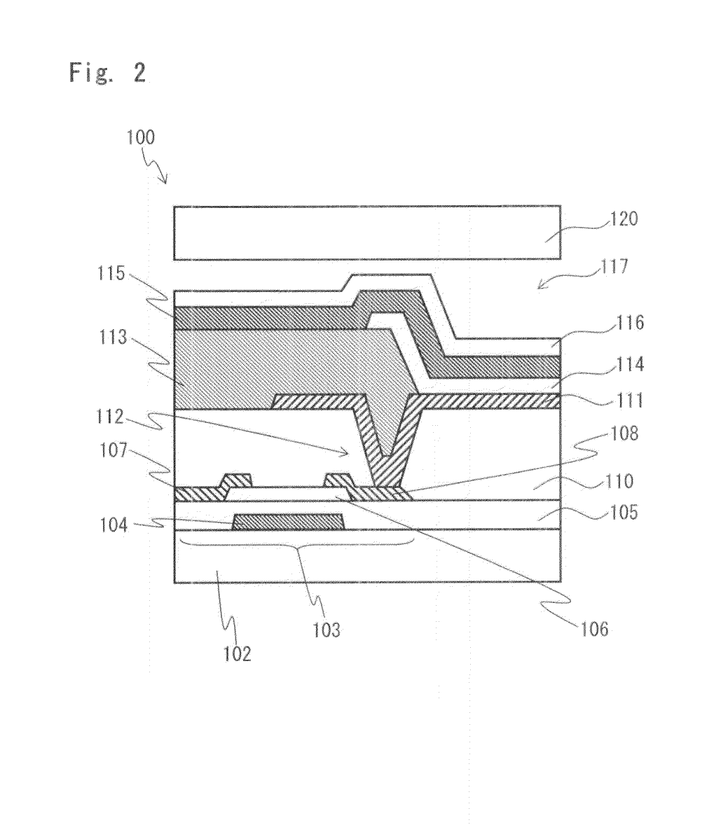

### DETAILED DESCRIPTION OF THE EMBODIMENTS

### Embodiment 1

Hereinafter the exemplary embodiments of the present invention will be explained with suitably referring to the drawings.

In the present invention, the “radioactive ray” that is irradiated during exposure is a concept encompassing visible ray, ultraviolet ray, far-ultraviolet ray, X-ray, charged particle beam and the like.

### <Organic EL Display Element>

As the organic EL element of the present invention, the organic EL display element of the present invention will be explained.

Namely, the organic EL display element of the exemplary embodiment of the present invention will be explained by using a drawing.

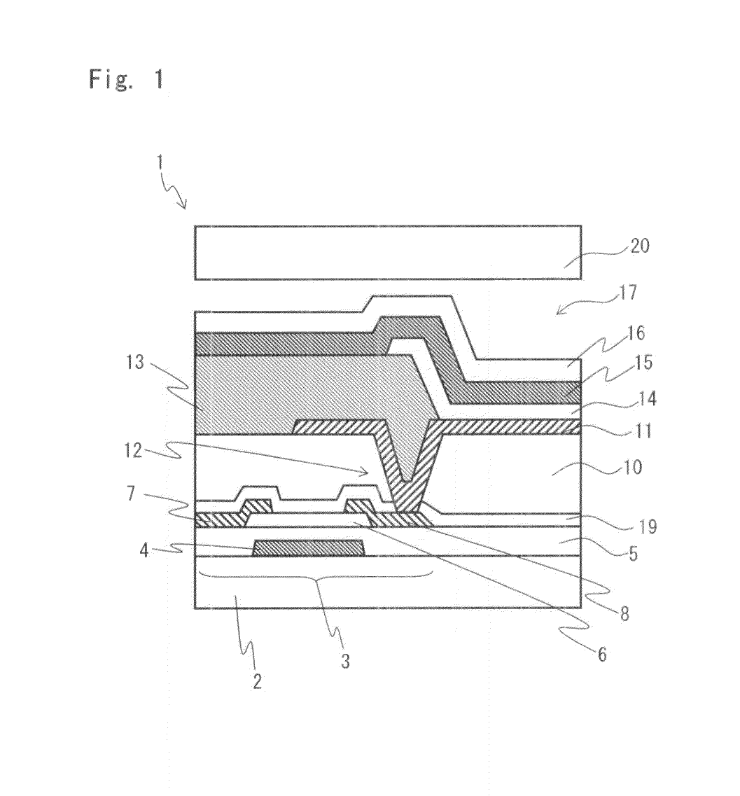

FIG. 1 is a cross-sectional view for schematically explaining the structure of the major part of the organic EL display element of the present exemplary embodiment.

The organic EL display element 1 of the present exemplary embodiment is an active matrix-type organic EL display element having plural pixels that are formed in a matrix pattern. The organic EL display element 1 may be of either a top-emission type or a bottom-emission type. Each pixel part of the organic EL display element 1 has a thin film transistor (hereinafter also referred to as TFT) 3 as an active element, which is disposed on a substrate 2.

With respect to the substrate 2 of the organic EL display element 1, in the case where the organic EL display element 1 is of a bottom-emission type, the substrate 2 is required to be transparent. Therefore, as examples of the material for the substrate 2, transparent resins such as PET (polyethylene telephthalate), PEN (polyethylene naphthalate) and PI (polyimide), and glasses such as non-alkali glass are used. On the other hand, in the case where the organic EL display element 1 is of a top-emission type, the substrate 2 does not need to be transparent, and thus any insulating body can be used as the material for the substrate 2. Similarly to the bottom-emission type, glass materials such as non-alkali glass can also be used.

The TFT 3 is constituted by having, on the substrate 2, a gate electrode 4 that is configured to form a part of a scan signal line (not depicted), a gate insulating film 5 that is configured to cover the gate electrode 4, a semiconductor layer 6 disposed through the gate insulating film 5 on the gate electrode 4, a first source-drain electrode 7 that is configured to connect to the semiconductor layer 6 by forming a part of an image signal line (not depicted), and a second source-drain electrode 8 that is configured to connect to the semiconductor layer 6.

The gate electrode 4 can be formed by forming a metal thin film on the substrate 2 by a deposition process, a sputtering process or the like, and conducting patterning utilizing an etching process. Furthermore, it is also possible to conduct patterning and use a metal oxide electroconductive film or an organic electroconductive film.

Examples of the material for the metal thin film that constitutes the gate electrode 4 may include metals such as aluminum (Al), copper (Cu), molybdenum (Mo), chromium (Cr), tantalum (Ta), titanium (Ti), gold (Au), tungsten (W) and silver (Ag), alloys of those metals, and alloys such as Al—Nd and an APC alloy (an alloy of silver, palladium and copper). Furthermore, it is also possible to use a laminate film formed of layers of different materials such as a laminate film of Al and Mo as the metal thin film.

Examples of the material for the metal oxide electroconductive film that constitutes the gate electrode 4 may include metal oxide electroconductive films such as tin oxide, zinc oxide, indium oxide, ITO (Indium Tin Oxide: indium-doped tin oxide) and indium zinc oxide (IZO).

Furthermore, examples of the materials for the organic electroconductive film may include electroconductive organic compounds such as polyaniline, polythiophene and polypyrrole, or mixtures of these compounds.

It is preferable that the thickness of the gate electrode 11 is adjusted to 10 nm to 1,000 nm.

The gate insulating film 5 that is disposed so as to cover the gate electrode 4 can be formed by forming an oxide film or a nitride film by a sputtering process, a CVD process, a deposition process or the like. The gate insulating film 5 can be formed by, for example, using metal oxides such as SiO₂ and metal nitrides such as SiN alone or by laminating those. It is also possible to constitute from an organic material such as a polymeric material. The film thickness of the gate insulating film 5 is preferably 10 nm to 10 μm, and specifically in the case where an inorganic material such as a metal oxide is used, the film thickness is preferably 10 nm to 1,000 nm, and in the case where an organic material is used, the film thickness is preferably 50 nm to 10 μm.

The first source-drain electrode 7 and second source-drain electrode 8, which connect to the semiconductor layer 6, can be formed by forming electroconductive films that constitute those electrodes by using a process such as a printing process and a coating process, and a sputtering process, a CVD process and a deposition process, and subjecting these films to patterning utilizing a photolithography process or the like. Examples of the constitutional material for the first source-drain electrode 7 and the second source-drain electrode 8 may include metals such as Al, Cu, Mo, Cr, Ta, Ti, Au, W and Ag, alloys of those metals, and alloys such as Al—Nd and APC. Furthermore, examples may include electroconductive metal oxides such as tin oxide, zinc oxide, indium oxide, ITO, indium zinc oxide (IZO), aluminum-doped zinc oxide (AZO) and gallium-doped zinc oxide (GZO), and electroconductive organic compounds such as polyaniline, polythiophene and polypyrrole. Furthermore, it is also possible to use laminate films formed of layers of different materials such as laminate films of Ti and Al as the electroconductive films that constitute those electrodes.

It is preferable that the thicknesses of the first source-drain electrode 7 and the second source-drain electrode 8 are each adjusted to 10 nm to 1,000 nm.

The semiconductor layer 6 can be formed by, for example, using a silicon (Si) material such as a-Si (amorphous-silicon) in an amorphous state, or p-Si (polysilicon) obtained by crystallizing a-Si by excimer laser or solid phase growth, or the like.

Furthermore, the semiconductor layer 6 of the TFT 3 can be used by using an oxide. Examples of the oxide that can be applied to the semiconductor layer 6 may include monocrystalline oxides, polycrystalline oxides and amorphous oxides, and mixture of these oxides. Examples of the polycrystalline oxides may include zinc oxide (ZnO) and the like.

Examples of the amorphous oxides that can be applied to the semiconductor layer 6 may include amorphous oxides constituted by containing at least one of indium (In), zinc (Zn) and tin (Sn).

Specific examples of the amorphous oxides that can be applied to the semiconductor layer 6 may include Sn—In—Zn oxide, In—Ga—Zn oxide (IGZO: indium gallium zinc oxide), In—Zn—Ga—Mg oxide, Zn—Sn oxide (ZTO: zinc tin oxide), In oxide, Ga oxide, In—Sn oxide, In—Ga oxide, In—Zn oxide (IZO: indium zinc oxide), Zn—Ga oxide, Sn—In—Zn oxide and the like. In the above-mentioned cases, the composition ratio of the constitutional materials is not necessarily 1:1, and a composition ratio that attains a desired property can be selected.

In the case where the semiconductor layer 6 using an amorphous oxide is formed by, for example, using IGZO or ZTO by a sputtering process or a deposition process, a layer of such material is formed by using an IGZO target or a ZTO target. Furthermore, the semiconductor layer 6 is formed by conducting patterning by a resist process and an etching process by utilizing a photolithography process or the like. It is preferable to adjust the thickness of the semiconductor layer 6 using an amorphous oxide to 1 nm to 1,000 nm.

In the case where the above-mentioned oxide is used in the semiconductor layer 6 of the TFT 3, it is preferable to dispose a protective layer (not depicted) that is formed of, for example, SiO₂ having a thickness of 5 nm to 80 nm, onto the area on which the first source-drain electrode 7 and the second source-drain electrode 8 are not formed of the upper surface of the semiconductor layer 6. This protective layer also referred to as an etching stopper layer or a stop layer, or the like.

By using the oxides exemplified above, the semiconductor layer 6 having high mobility can be formed at a low temperature, and the TFT 3 having an excellent performance can be provided.

Examples of oxides that are specifically preferable for forming the semiconductor layer 6 of the semiconductor element 1 of the present exemplary embodiment may include zinc oxide (ZnO), indium gallium zinc oxide (IGZO), zinc tin oxide (ZTO) and zinc indium oxide (ZIO).

By using these oxides, the semiconductor layer 6 that is excellent in mobility is formed at a lower temperature, and the TFT 3 is possible to show a high ON/OFF ratio.

An inorganic insulating film 19 can be disposed on the TFT 3 so as to cover the TFT 3. The inorganic insulating film 19 can be formed by, for example, using metal oxides such as SiO₂ and metal nitrides such as SiN alone or as a laminate. The inorganic insulating film 19 is disposed so as to protect the semiconductor layer 6, for example, to prevent the semiconductor layer 6 from being affected by humidity. In addition, it is also possible that the organic EL display element 1 of the present exemplary embodiment has a structure in which a protective film 10 mentioned below, which is an insulating film formed of an organic material, is disposed on the TFT 3 without disposing the inorganic insulating film 19.

Next, in the organic EL display element 1, a protective film 10 is disposed on the inorganic insulating film 19 so as to cover the upper side of the TFT 3 on the substrate 2. This protective film 10 has a function to planarize the unevenness due to the TFT 3 formed on the substrate 2. The protective film 10 is an insulating cured film that is formed by using the radiation-sensitive resin composition of the present exemplary embodiment, which will be mentioned below in detail, and is an organic insulating film that is formed by using an organic material. It is preferable that the protective film 10 has an excellent function as a planarizing film, and from this viewpoint, it is preferable that the protective film 10 is formed to be thick. For example, the protective film 10 can be formed at a film thickness of 1 μm to 6 μm. The structure and formation of the protective film 10 will be mentioned below in detail.

An anode 11, which is a first electrode that constitutes a pixel electrode, is disposed on the protective film 10. The anode 11 is formed of an electroconductive material. It is preferable to select the material for the anode 11 having a different property depending on whether the type of the organic EL display element 1 is a bottom-emission type or a top-emission type. In the case of a bottom-emission type, the anode 11 is required to be transparent. Therefore, as the material for the anode 11, ITO (Indium Tin Oxide), IZO (Indium Zinc Oxide), tin oxide or the like is selected. On the other hand, in the case where the organic EL display element 1 is of a top-emission type, light reflectivity is required for the anode 11. Therefore, as the material for the anode 11, an APC alloy (an alloy of silver, palladium and copper), ARA (an alloy of silver, rubidium and gold), MoCr (an alloy of molybdenum and chromium), NiCr (an alloy of nickel and chromium) or the like is selected. It is preferable to adjust the thickness of the anode 11 to 100 nm to 500 nm.

In order for the anode 11 disposed on the protective film 10 to connect to the second source-drain electrode 8, a through-hole 12 that penetrates the protective film 10 is formed on the protective film 10. The through-hole 12 is formed so as to penetrate also the inorganic insulating film 19 positioned below the protective film 10. As mentioned below, the protective film 10 can be formed by using the radiation-sensitive resin composition of the present exemplary embodiment. Therefore, the through-hole 12 can be completed by, for example, irradiating the coating of the radiation-sensitive resin composition with radioactive ray and forming a penetrating hole having a desired shape to thereby form the protective film 10, and conducting dry etching on the inorganic insulating film 19 using this protective film 10 as a mask. Meanwhile, in the case of a structure in which the inorganic insulating film 19 is not disposed on the TFT 3, the penetrating hole that is formed by irradiating the protective film 10 with radioactive ray constitutes the through-hole 12. As a result, the anode 11 covers at least apart of the protective film 10, and can be connected to the second source-drain electrode 8 that is connected to the TFT 3, through the through-hole 12 that is disposed on the protective film 10 so as to penetrate the protective film 10.

In the organic EL display element 1, a bank 13, which is a division wall for defining an arranging area for an organic luminescent layer 14, is disposed on the anode 11 on the protective film 10. The bank 13 can be produced as a cured film by patterning a coating formed by using the radiation-sensitive resin composition of the present exemplary embodiment, which will be mentioned below in detail, and can have, for example, a shape in a grid-like pattern in planar view. The organic luminescent layer 14, which emits light in an electric field, is disposed in the area defined by this bank 13. In the organic EL display element 1, the bank 13 is a barrier wall that encompasses the surrounding of the organic luminescent layer 14 to thereby section the respective plural pixels that are adjacent to each other.

In the organic EL display element 1, the height of the bank 13 (the distance between the upper surface of the bank 13 and the upper surface of the anode 11 in the arranging area for the organic luminescent layer 14) is preferably 0.1 μm to 2 μm, more preferably 0.8 μm to 1.2 μm. In the case where the height of the bank 13 is more than 2 μm, the upper side of the bank 13 may strike against a sealing substrate 20. In the case where the height of the bank 13 is less than 0.1 μm, an ink-like luminescent material composition that has been applied to the area defined by the bank 13 by an inkjet process may leak from the bank 13.

The bank 13 of the organic EL display element 1 can be formed as a cured film by using the radiation-sensitive resin composition of the present exemplary embodiment, which will be mentioned below in detail, and subjecting a coating of the composition to patterning and the like. Namely, the bank 13 can be constituted by containing a resin. As mentioned below, since the bank 13 defines an area to which an ink-like luminescent material composition containing an organic luminescent material is applied, it is preferable that the bank 13 has low wettability. In the case where the wettability of the bank 13 is controlled to be specifically low, it is possible to subject the bank 13 to a plasma treatment with a fluorine gas, or a liquid repellent may be incorporated in the radiation-sensitive resin composition of the present exemplary embodiment that forms the bank 13. Since a plasma treatment may adversely affect the other constitutional elements of the organic EL display element 1, it is preferable in some cases to incorporate the liquid repellent in the radiation-sensitive resin composition of the present exemplary embodiment that forms the bank 13. The formation of the bank 13 will be mentioned below in detail.

The organic luminescent layer 14 that emit light upon application of an electric field is disposed in the area defined by the bank 13. The organic luminescent layer 14 is a layer containing an organic luminescent material that emits light in an electric field.

The organic luminescent material included in the organic luminescent layer 14 may be a low molecular weight organic luminescent material or a polymeric organic luminescent material, and in the case where a process for applying an organic luminescent material by an inkjet process is used, a polymeric organic luminescent material that is preferable for that process is preferable. As the polymeric organic luminescent material, for example, polyphenylene vinylene and derivatives thereof, poly acetylene and derivatives thereof, polyphenylene and derivatives thereof, poly paraphenylene ethylene and derivatives thereof, poly 3-hexyl thiophene (P3HT) and derivatives thereof, polyfluorene (PF) and derivatives thereof and the like can be selected and used.

The organic luminescent layer 14 is disposed on the anode 11 in the area defined by the bank 13. It is preferable that the organic luminescent layer 14 has a thickness of 50 nm to 100 nm. The thickness of the organic luminescent layer 14 as used herein means the distance from the bottom surface of the organic luminescent layer 14 on the anode 11 to the upper surface of the organic luminescent layer 14 on the anode 11.

In addition, a hole injection layer and/or an intermediate layer may be disposed between the anode 11 and organic luminescent layer 14. In the case where the hole injection layer and/or an intermediate layer is/are disposed between the anode 11 and organic luminescent layer 14, the hole injection layer is disposed on the anode 11, the intermediate layer is disposed on the hole injection layer, and the organic luminescent layer 14 is disposed on the intermediate layer. Alternatively, the hole injection layer and intermediate layer may be omitted as long as holes can be efficiently transported from the anode 11 to organic luminescent layer 14.

In the organic EL display element 1, a cathode 15, which is a second electrode, is formed so as to cover the organic luminescent layer 14 and also cover the bank 13 for the sectioning the pixels. The cathode 15 is formed so as to commonly cover the plural pixels to thereby constitute a common electrode for the organic EL display element 1.

The organic EL display element 1 of the present exemplary embodiment has the cathode 15 on the organic luminescent layer 14, and the cathode 15 is formed of an electroconductive element. The material used for forming the cathode 15 differs depending on whether the organic EL display element 1 is a bottom-emission type or a top-emission type. In the case of a top-emission type, the cathode 15 is preferably an ITO electrode, an IZO electrode or the like that constitutes a visible light-translucent electrode. On the other hand, in the case where the organic EL display element 1 is of a bottom-emission type, the cathode 15 does not need to have visible light translucency. In such case, although the constitutional material for the cathode 15 is not specifically limited as long as it is electroconductive, it is possible to select, for example, an alloy containing barium (Ba), barium oxide (BaO), aluminum (Al) and Al, or the like.

In addition, an electron injection layer formed of, for example, barium (Ba), lithium fluoride (LiF) and the like may be disposed between the cathode 15 and organic luminescent layer 14.

A passivation film 16 can be disposed on the cathode 15. The passivation film 16 can be formed by using metal nitrides such as SiN and aluminum nitride (AlN) alone or as a laminate. By the action of the passivation film 16, intrusion of moisture and oxygen into the organic EL display element 1 can be suppressed.

It is preferable to seal the main surface on which the organic luminescent layer 14 is disposed of the thus-constituted substrate 2, with the sealing substrate 20 through the sealing layer 17 by using a sealant (not depicted) that is applied in the vicinity of the outer periphery end part. The sealing layer 17 can be a layer of inert gas such as dried nitrogen gas or a layer of a filler material such as an adhesive. Furthermore, as the sealing substrate 20, a glass substrate such as non-alkali glass can be used.

In addition, it is also possible that the organic EL display element of the present exemplary embodiment has a bottom-emission type having a structure in which a protective film for covering the upper side of the TFT is not disposed. In such case, the anode, which is the first electrode, is connected to the second source-drain electrode and thus connected to the TFT without the protective film. Furthermore, the organic luminescent layer is disposed on the anode. At this time, the bank is disposed on the TFT to thereby define an arranging area for the organic luminescent layer. The cathode, which is the second electrode, is disposed on the organic luminescent layer.

Next, the protective film 10 and bank 13, which are the major constitutional elements of the organic EL display element 1 of the present exemplary embodiment and the radiation-sensitive resin composition used for forming them will be explained in more detail. The radiation-sensitive resin composition of the present exemplary embodiment is preferable for forming the protective film of the organic EL element of the exemplary embodiment of the present invention and is also preferable for forming the bank, and thus is preferably used for forming the protective film 10 and bank 13, which are the major constitutional elements of the organic EL display element 1 of the exemplary embodiment of the present invention.

### <Protective Film>

The protective film of the exemplary embodiment of the present invention is formed by using the radiation-sensitive resin composition of the present exemplary embodiment mentioned below, and is preferable as a protective film for the organic EL element of the exemplary embodiment of the present invention, and can be preferably used as a protective film for the organic EL display element of the above-mentioned present exemplary embodiment. Hereinafter the protective film, which is the major constitutional element of the organic EL display element of the present exemplary embodiment, will be explained.

As mentioned above, the organic EL display element of the present exemplary embodiment has a protective film that covers the upper side of the TFT on the substrate. The protective film of the present exemplary embodiment is constituted by containing a resin to thereby have an insulating property, and also has a function to planarize the unevenness due to the TFT on the substrate.

Furthermore, as mentioned above, an anode is disposed on the upper layer of the protective film, and the protective film is constituted to have a through-hole so that the connection of the TFT positioned on the lower layer of the protective film and the anode positioned on the upper layer is enabled.

The protective film is formed by using the radiation-sensitive resin composition of the present exemplary embodiment, which will be explained below, so that the formation of the through-hole having such desired shape would be attained at a high accuracy. The radiation-sensitive resin composition of the present exemplary embodiment is constituted by containing a resin and a compound having a quinonediazide structure so that patterning of a coating of the composition at a high resolution would be attained to thereby enable formation of the protective film as a cured film having a through-hole and the like. It is preferable that the resin has alkali-developablility. As a result, the protective film is formed as a cured film by applying the radiation-sensitive resin composition of the present exemplary embodiment to the substrate on which the TFT is formed, subjecting the substrate to necessary patterning such as formation of a through-hole, and conducting curing by heating.

At this time, the formed protective film can contain the compound having a quinonediazide structure, which is the component of the radiation-sensitive resin composition, together with the resin. As a result, excellent light shielding property can be attained.

In TFTs using silicon (Si) such as a-Si and p-Si in a semiconductor layer, in the cases when they are used in display elements, a light-shielding means is disposed in many cases so that light from outside would not enter into the semiconductor layer. Furthermore, in the cases of semiconductor layers formed by using amorphous oxides such as IGZO, the semiconductor layers have absorption in the ultraviolet region and the like in some cases. Therefore, as described in JP 2007-115902 A, in TFTs using an amorphous oxide in a semiconductor layer, the resistance during OFF sometimes decrease when light was irradiated from outside, and as a result, a sufficient ON/OFF ratio was sometimes not able to be obtained when the TFTs were used as switching elements for display elements. Therefore, in the cases of organic EL display elements having such TFTs, deterioration of the properties due to the effect of the light from outside was sometimes problematic.

With respect to such problem of conventional organic EL display elements, the organic EL display element of the present exemplary embodiment, which has the above-mentioned protective film that covers the TFT, enables light-shielding of the semiconductor layer of the TFT by the effect of the protective film. Furthermore, the organic EL display element of the present exemplary embodiment can decrease the decreasing in the properties due to the effect of light by the light-shielding effect of the protective film. The light-shielding function of the protective film by containing such compound having a quinonediazide structure is specifically effective for an organic EL display element having a TFT of a semiconductor layer using an amorphous oxide such as IGZO that has a significant problem in light resistance as mentioned above.

At this time, specifically, excellent visible light translucency is sometimes required in the cases of an organic EL display element of a bottom-emission type, and it is sometimes considered to be not preferable that the protective film has light shielding property.

However, the organic EL display element of the present exemplary embodiment can preferably control the balance between light translucency and light shielding property that are required for a protective film for an organic EL display element, by using the protective film containing the compound having a quinonediazide structure.

When the compound having a quinonediazide structure is exposed to light, the molecular structure thereof is changed, and the compound is a compound having an indenecarboxylic acid structure, and thus the light absorption performance of the molecule is changed. Namely, the compound having a quinonediazide structure has a property referred to as a photobleaching property. Therefore, in the organic EL display element of the present exemplary embodiment, in the case where a defect occurs in the light translucency after formation of the protective film, it is possible to adjust the light translucency by only irradiating the protective film with light.

Therefore, the protective film of the organic EL display element of the present exemplary embodiment contains at least one of the compound having a quinonediazide structure and the compound having an indenecarboxylic acid structure, together with the resin. Furthermore, the protective film is a specifically preferable protective film in the case where the organic EL display element of the present exemplary embodiment is of a bottom-emission type.

As mentioned above, in the organic EL display element of the present exemplary embodiment, the protective film thereof shows the above-mentioned inherent effect besides a function to effect planarization, a patterning property and the like. Therefore, the formation of the protective film of the organic EL element of the present exemplary embodiment will be subsequently explained. Specifically, the formation of the protective film of the organic EL display element of the present exemplary embodiment will be explained in more detail. Furthermore, the radiation-sensitive resin composition used for forming the protective film will be explained in detail.

### <Radiation-Sensitive Resin Composition>

In the organic EL element of the present exemplary embodiment, the radiation-sensitive resin composition of the present exemplary embodiment, which is used for the production of the protective film that is a constitutional element, contains a resin and a compound having a quinonediazide structure as essential components. Therefore, in the organic EL display element of the present exemplary embodiment, the radiation-sensitive resin composition of the present exemplary embodiment, which is used for the production of the protective film that is the constitutional element of the organic EL display element, contains a resin and a compound having a quinonediazide structure as essential components. Furthermore, the radiation-sensitive resin composition can further contain an ultraviolet absorber.

The resin that is contained in the radiation-sensitive resin composition of the present exemplary embodiment is preferably a resin having an alkali-developability. By containing such composition, a cured film formed of the radiation-sensitive resin composition of the present exemplary embodiment can have an excellent patterning property and can constitute a protective film having a highly-controlled desired shape. Furthermore, by containing the compound having a quinonediazide structure, the cured film can also possess a controllable light shielding property. Furthermore, in the case where an ultraviolet absorber is contained, the effect of ultraviolet ray on the TFT can be decreased. In addition, the radiation-sensitive resin composition of the present exemplary embodiment can contain a curing promoter that promotes the curing of the formed film, and can further contain other optional components as long as the effect of the present invention is not impaired.

Furthermore, it is known in organic EL display elements that an organic luminescent layer is quickly deteriorated upon contacting with moisture and the luminescent state thereof is inhibited, whether the organic luminescent layer is a low molecular weight-organic luminescent layer using a low molecular weight material or a polymeric organic luminescent layer using a polymeric material. It is considered that there are cases when such moisture intrudes from an outer environment and when a trace amount of moisture that is included in the protective film-forming material, bank-forming material and the like gradually intrudes into the organic luminescent layer.

Therefore, a material that can form a protective film that prevents the intrusion of impurities (mainly moisture) into the organic luminescent layer and decreases the inhibition of the luminescence of the organic luminescent layer is required. Similarly, a material that can form a bank that prevents the intrusion of impurities (mainly moisture) into the organic luminescent layer and decreases the inhibition of the luminescence of the organic luminescent layer is required. As mentioned above, such material for forming the protective film is required to have a resolution that enables formation of a through-hole and a function to effect planarization.

Also in view of such impurities such as moisture, an optimal resin is selected as the resin to be included in the radiation-sensitive resin composition of the present exemplary embodiment.

Hereinafter the component to be included in the radiation-sensitive resin composition of the present exemplary embodiment will be explained in detail.

### [Resin]

The resin included in the radiation-sensitive resin composition of the present exemplary embodiment is preferably a resin having an alkali-developability so that a protective film to be formed would have an excellent patterning property. Furthermore, a resin that suppresses the intrusion of impurities (mainly moisture) into the organic luminescent layer is preferable. From such viewpoint, the resin included in the radiation-sensitive resin composition of the present exemplary embodiment is preferably formed of at least one selected from an acrylic resin having a carboxyl group, a polyimide resin, a polysiloxane and a novolak resin. Furthermore, these respective resins can be used alone, or can be used by mixing.

Although use of the resins by mixing is not specifically limited, in such case, from the above-mentioned viewpoint, it is specifically preferable to use a novolak resin by mixing it with other resin. Furthermore, it is preferable to use a novolak resin and an acrylic resin having a carboxyl group by mixing, and to use a novolak resin and a polyimide resin by mixing.

Hereinafter the acrylic resin having a carboxyl group, polyimide resin, polysiloxane and novolak resin, which are preferable as the resins to be incorporated in the radiation-sensitive resin composition of the present exemplary embodiment, will be respectively explained in more detail.

### [Acrylic Resin Having Carboxyl Group]

The acrylic resin having a carboxyl group, which is preferable as the resin, preferably contains a constitutional unit having a carboxyl group and a constitutional unit having a polymerizable group. In such case, the acrylic resin having a carboxyl group is not specifically limited as long as it contains the constitutional unit having a carboxyl group and the constitutional unit having a polymerizable group, and has an alkali-developability.

The constitutional unit having a polymerizable group is at least one of constitutional unit selected from the group consisting of a constitutional unit having an epoxy group and a constitutional unit having a (meth)acryloyloxy group. Since the acrylic resin having a carboxyl group contains the above-mentioned specific constitutional unit, a cured film having excellent surface curability and curability in deep portions can be formed, and thus the protective film of the present exemplary embodiment can be formed.

The constitutional unit having a (meth)acryloyloxy group can be formed by, for example, a method including reacting (meth)acrylic acid with an epoxy group in a copolymer, a method including reacting a (meth)acrylic acid ester having an epoxy group with a carboxyl group in a copolymer, a method including reacting a (meth)acrylic acid ester having an isocyanate group with a hydroxyl group in a copolymer, a method including reacting a (meth)acrylic acid hydroxy ester with an acid anhydride site in a copolymer, or the like. Among these, the method including reacting a (meth)acrylic acid ester having an epoxy group with a carboxyl group in a copolymer is specifically preferable.

The acrylic resin containing the constitutional unit having a carboxyl group and the constitutional unit having an epoxy group as a polymerizable group can be synthesized by copolymerizing (A1) at least one selected from the group consisting of an unsaturated carboxylic acid and an unsaturated carboxylic acid anhydride (hereinafter also referred to as “compound (A1)”) and (A2) an epoxy group-containing unsaturated compound (hereinafter also referred to as “compound (A2)”). In this case, the acrylic resin having a carboxyl group is a copolymer containing a constitutional unit formed of at least one selected from the group consisting of an unsaturated carboxylic acid and an unsaturated carboxylic acid anhydride and a constitutional unit formed of an epoxy group-containing unsaturated compound.

The acrylic resin having a carboxyl group can be produced by, for example, copolymerizing compound (A1), which gives a carboxyl group-containing constitutional unit and compound (A2), which gives an epoxy group-containing constitutional unit, in a solvent in the presence of a polymerization initiator. Furthermore, (A3) a hydroxyl group-containing unsaturated compound, which gives a hydroxyl group-containing constitutional unit (hereinafter also referred to as “compound (A3)”) can further be added to give a copolymer. In addition, in the production of the acrylic resin having a carboxyl group, compound (A4) (an unsaturated compound, which gives a constitutional unit other than the constitutional units derived from the above-mentioned compounds (A1), (A2) and (A3)) can be added together with the above-mentioned compound (A1), compound (A2) and compound (A3) to give a copolymer. Hereinafter the respective compounds will be described in detail.

### [Compound (A1)]

Compound (A1) may include unsaturated monocarboxylic acids, unsaturated dicarboxylic acids, anhydrides of unsaturated dicarboxylic acids, mono[(meth)acryloyloxyalkyl]esters of polyhydric carboxylic acids and the like.

Examples of the unsaturated monocarboxylic acids may include acrylic acid, methacrylic acid, crotonic acid and the like.

Examples of the unsaturated dicarboxylic acids may include maleic acid, fumaric acid, citraconic acid, mesaconic acid, itaconic acid and the like.

Examples of the anhydrides of unsaturated dicarboxylic acids may include anhydrides of the compounds exemplified as the above-mentioned dicarboxylic acids, and the like.

Among these compounds (A1), acrylic acid, methacrylic acid and maleic anhydride are preferable, and acrylic acid, methacrylic acid and maleic anhydride are more preferable from the viewpoints of copolymerization reactivity, solubility in an alkali aqueous solution and easy availability.

These compounds (A1) may be used alone or by mixing two or more.

The rate of use of compound (A1) is preferably 5 mass % to 30 mass %, more preferably 10 mass % to 25 mass %, based on the total of compound (A1) and compound (A2) (where necessary, optional compounds (A3) and (A4)). By adjusting the rate of use of compound (A1) to 5 mass % to 30 mass %, the solubility of the acrylic resin having a carboxyl group in an alkali aqueous solution can be optimized, and the protective film of the present exemplary embodiment can be formed as a cured film having excellent radioactive ray sensitivity.

### [Compound (A2)]

Compound (A2) is an epoxy group-containing unsaturated compound having a radical polymerizability. Examples of the epoxy group may include an oxiranyl group (a 1,2-epoxy structure) or an oxetanyl group (a 1,3-epoxy structure), and the like.

Examples of the unsaturated compound having an oxiranyl group may include glycidyl acrylate, glycidyl methacrylate, 2-methylglycidyl methacrylate, 3,4-epoxybutyl acrylate, 3,4-epoxybutyl methacrylate, 6,7-epoxyheptyl acrylate, 6,7-epoxyheptyl methacrylate, 6,7-epoxyheptyl α-ethylacrylate, o-vinylbenzyl glycidyl ether, m-vinylbenzyl glycidyl ether, p-vinylbenzyl glycidyl ether, 3,4-epoxycyclohexylmethyl methacrylate and the like. Among these, glycidyl methacrylate, 2-methylglycidyl methacrylate, 6,7-epoxyheptyl methacrylate, o-vinylbenzyl glycidyl ether, m-vinylbenzyl glycidyl ether, p-vinylbenzyl glycidyl ether, 3,4-epoxycyclohexyl methacrylate, 3,4-epoxycyclohexyl acrylate and the like are preferable from the viewpoints of improvement of the copolymerization reactivity and the solvent resistance of the protective film.

Examples of the unsaturated compound having an oxetanyl group may include:

acrylic acid esters such as 3-(acryloyloxymethyl)oxetane, 3-(acryloyloxymethyl)-2-methyloxetane, 3-(acryloyloxymethyl)-3-ethyloxetane, 3-(acryloyloxymethyl)-2-phenyloxetane, 3-(2-acryloyloxyethyl)oxetane, 3-(2-acryloyloxyethyl)-2-ethyloxetane, 3-(2-acryloyloxyethyl)-3-ethyloxetane and 3-(2-acryloyloxyethyl)-2-phenyloxetane;

methacrylic acid esters such as 3-(methacryloyloxymethyl)oxetane, 3-(methacryloyloxymethyl)-2-methyloxetane, 3-(methacryloyloxymethyl)-3-ethyloxetane, 3-(methacryloyloxymethyl)-2-phenyloxetane, 3-(2-methacryloyloxyethyl)oxetane, 3-(2-methacryloyloxyethyl)-2-ethyloxetane, 3-(2-methacryloyloxyethyl)-3-ethyloxetane, 3-(2-methacryloyloxyethyl)-2-phenyloxetane and 3-(2-methacryloyloxyethyl)-2,2-difluorooxetane, and the like.

Among these compounds (A2), glycidyl methacrylate, 3,4-epoxycyclohexyl methacrylate and 3-(methacryloyloxymethyl)-3-ethyloxetane are preferable. These compounds (A2) may be used alone or by mixing two or more.

The ratio of use of compound (A2) is preferably 5 mass % to 60 mass %, more preferably 10 mass % to 50 mass %, based on the total of the compound (A1) and compound (A2) (where necessary, optional compounds (A3) and (A4)). By adjusting the ratio of use of compound (A2) to 5 mass % to 60 mass %, a cured film having excellent curability can be formed, and the protective film of the present exemplary embodiment can be formed.

### [Compound (A3)]

Examples of compound (A3) may include (meth)acrylic acid esters having a hydroxyl group, (meth)acrylic acid esters having a phenolic hydroxyl group and hydroxystyrenes.

Examples of the acrylic acid esters having a hydroxyl group may include 2-hydroxyethyl acrylate, 3-hydroxypropyl acrylate, 4-hydroxybutyl acrylate, 5-hydroxypentyl acrylate, 6-hydroxyhexyl acrylate and the like.

Examples of the methacrylic acid esters having a hydroxyl group may include 2-hydroxyethyl methacrylate, 3-hydroxypropyl methacrylate, 4-hydroxybutyl methacrylate, 5-hydroxypentyl methacrylate, 6-hydroxyhexyl methacrylate and the like.

Examples of the acrylic acid esters having a phenolic hydroxyl group may include 2-hydroxyphenyl acrylate, 4-hydroxyphenyl acrylate and the like. Examples of the methacrylic acid esters having a phenolic hydroxyl group may include 2-hydroxyphenyl methacrylate, 4-hydroxyphenyl methacrylate and the like.

As the hydroxystyrenes, o-hydroxystyrene, p-hydroxystyrene and α-methyl-p-hydroxystyrene are preferable. These compounds (A3) may be used alone or by mixing two or more.

The ratio of use of compound (A3) is preferably 1 mass % to 30 mass &, more preferably 5 mass % to 25 mass %, based on the total of the compound (A1), compound (A2) and compound (A3) (where necessary, optional compound (A4)).

### [Compound (A4)]

The compound (A4) is not specifically limited as long as it is an unsaturated compound other than the above-mentioned compound (A1), compound (A2) and compound (A3). Examples of compound (A4) may include unsaturated compounds having methacrylic acid chain alkyl esters, methacrylic acid cyclic alkyl esters, acrylic acid chain alkyl esters, acrylic acid cyclic alkyl esters, methacrylic acid aryl esters, acrylic acid aryl esters, unsaturated dicarboxylic acid diesters, maleimide compounds, unsaturated aromatic compounds, conjugate dienes, tetrahydrofuran backbones and the like, and other unsaturated compounds, and the like.

Examples of the methacrylic acid chain alkyl esters may include methyl methacrylate, ethyl methacrylate, n-butyl methacrylate, sec-butyl methacrylate, t-butyl methacrylate, 2-ethylhexyl methacrylate, isodecyl methacrylate, n-lauryl methacrylate, tridecyl methacrylate, n-stearyl methacrylate and the like.

Examples of the methacrylic acid cyclic alkyl esters may include cyclohexyl methacrylate, 2-methylcyclohexyl methacrylate, tricyclo[5.2.1.0^{2,6}]decan-8-yl methacrylate, tricyclo[5.2.1.0^{2,6}]decan-8-yloxyethyl methacrylate, isoboronyl methacrylate and the like.

Examples of the acrylic acid chain alkyl esters may include methyl acrylate, ethyl acrylate, n-butyl acrylate, sec-butyl acrylate, t-butyl acrylate, 2-ethylhexyl acrylate, isodecyl acrylate, n-lauryl acrylate, tridecyl acrylate, n-stearyl acrylate and the like.

Examples of the acrylic acid cyclic alkyl esters may include cyclohexyl acrylate, 2-methylcyclohexyl acrylate, tricyclo[5.2.1.0^{2,6}]decan-8-yl acrylate, tricyclo[5.2.1.0^{2,6}]decan-8-yloxyethyl acrylate, isoboronyl acrylate and the like.

Examples of the methacrylic acid aryl esters may include phenyl methacrylate, benzyl methacrylate and the like.

Examples of the acrylic acid aryl esters may include phenyl acrylate, benzyl acrylate and the like.

Examples of the unsaturated dicarboxylic acid diesters may include diethyl maleate, diethyl fumarate, diethyl itaconate and the like.

Examples of the maleimide compounds may include N-phenylmaleimide, N-cyclohexylmaleimide, N-benzylmaleimide, N-(4-hydroxyphenyl)maleimide, N-(4-hydroxybenzyl)maleimide, N-succinimidyl-3-maleimidebenzoate, N-succinimidyl-4-maleimidebutyrate, N-succinimidyl-6-maleimidecaproate, N-succinimidyl-3-maleimidepropionate, N-(9-acridinyl)maleimide and the like.

Examples of the unsaturated aromatic compounds may include styrene, α-methylstyrene, m-methylstyrene, p-methylstyrene, vinyltoluene, p-methoxystyrene and the like.

Examples of the conjugate dienes may include 1,3-butadiene, isoprene, 2,3-dimethyl-1,3-butadiene and the like.

Examples of the unsaturated compounds containing a tetrahydrofuran backbone may include tetrahydrofurfuryl methacrylate, 2-methacryloyloxy-propionic acid tetrahydrofurfuryl ester, 3-(meth)acryloyloxytetrahydrofuran-2-one and the like.

Examples of the other unsaturated compounds may include acrylonitrile, methacrylonotrile, vinyl chloride, vinylidene chloride, acrylamide, methacrylamide, vinyl acetate and the like.

Among these compounds (A4), methacrylic acid chain alkyl esters, methacrylic acid cyclic alkyl esters, methacrylic acid aryl esters, maleimide compounds, tetrahydrofuran backbones, unsaturated aromatic compounds, acrylic acid cyclic alkyl esters are preferable. Among these, styrene, methyl methacrylate, t-butyl methacrylate, n-lauryl methacrylate, benzyl methacrylate, tricyclo[5.2.1.0^{2,6}]decan-8-yl methacrylate, p-methoxystyrene, 2-methylcyclohexyl acrylate, N-phenylmaleimide, N-cyclohexylmaleimide and tetrahydrofurfuryl methacrylate are specifically preferable from the viewpoints of the copolymerization reactivity and solubility in an alkali aqueous solution.

These compounds (A4) may be used alone or by mixing two or more.

The rate of use of compound (A4) is preferably 10 mass % to 80 mass % based on the total of compound (A1), compound (A2) and compound (A4) (and optional compound (A3)).

### [Polyimide Resin]

The polyimide resin that is preferable as the resin for use in the radiation-sensitive resin composition of the present exemplary embodiment is a polyimide resin having at least one kind selected from the group consisting of a carboxyl group, a phenolic hydroxyl group, a sulfonic acid group and a thiol group in the constitutional unit of the polymer. By having these alkali-soluble groups in the constitutional unit, expression of scum on an exposed part can be suppressed during alkali developing. Furthermore, it is preferable to have a fluorine atom in the constitutional unit since water repellency is imparted to the interface of a film during developing with an alkali aqueous solution, and thus infiltration on the interface and the like are suppressed. The content of the fluorine atom in the polyimide resin is preferably 10 mass % or more so as to obtain a sufficient effect of preventing the infiltration on the interface, and more preferably 20 mass % or less from the viewpoint of the solubility in the alkali aqueous solution.

Although the polyimide resin that is preferable as the resin for use in the radiation-sensitive resin composition of the present exemplary embodiment is not specifically limited, it is preferably to have a structural unit represented by the following formula (I-1).

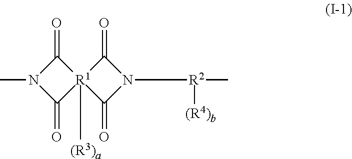

In the above-mentioned formula (I-1), R¹ represents a 4-to 14-valent organic group, and R² represents a 2- to 12-valent organic group.

In the above-mentioned formula (I-1), R³ and R⁴ each represents a carboxyl group, a phenolic hydroxyl group, a sulfonic acid group or a thiol group, and may be the same or different from each other. a and b each represents an integer of 0 to 10.

In the above-mentioned formula (I-1), R¹ represents a residue of tetracarboxylic dianhydride, and is a 4- to 14-valent organic group. Among these, an organic group having 5 to 40 carbon atoms containing an aromatic ring or a cyclic aliphatic group is preferable.

As the tetracarboxylic dianhydride, 3,3′,4,4′-biphenyltetracarboxylic dianhydride, 2,3,3′,4′-biphenyltetracarboxylic dianhydride, 2,2′,3,3′-biphenyltetracarboxylic dianhydride, 3,3′,4,4′-benzophenonetetracarboxylic dianhydride, 2,2′,3,3′-benzophenonetetracarboxylic dianhydride, 2,2-bis(3,4-dicarboxyphenyl)propane dianhydride, 2,2-bis(2,3-dicarboxyphenyl)propane dianhydride, 1,1-bis(3,4-dicarboxyphenyl)ethane dianhydride, 1,1-bis(2,3-dicarboxyphenyl)ethane dianhydride, bis(3,4-dicarboxyphenyl)methane dianhydride, bis(2,3-dicarboxyphenyl)methane dianhydride, bis(3,4-dicarboxyphenyl)sulfone dianhydride, bis(3,4-dicarboxyphenyl)ether dianhydride, 2,2-bis(3,4-dicarboxyphenyl)hexafluoropropane dianhydride, 3,3′,4,4′-diphenylsulfonetetracarboxylic dianhydride, 9,9-bis(3,4-dicarboxyphenyl)fluorene dianhydride, 9,9-bis{4-(3,4-dicarboxyphenoxy)phenyl}fluorene dianhydride or an acid dianhydride having the structure shown below, and the like are preferable. Two or more kinds of these may be used.

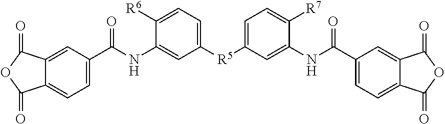

R⁵ represents an oxygen atom, C(CF)₂, C(CH₃)₂ or SO₂. Each of R⁶ and R⁷ represents a hydrogen atom, a hydroxyl group or a thiol group.

In the above-mentioned formula (I-1), R² represents a residue of a diamine, and is a 2- to 12-valent organic group. Of these, an organic group having 5 to 40 carbon atoms containing an aromatic ring or a cyclic aliphatic group is preferable.

As specific examples of the diamine, 3,3′-diaminodiphenyl ether, 3,4′-diaminodiphenyl ether, 4,4′-diaminodiphenyl ether, 3,3′-diaminodiphenylmethane, 3,4′-diaminodiphenylmethane, 4,4′-diaminodiphenylmethane, 3,3′-diaminodiphenylsulfone, 3,4′-diaminodiphenylsulfone, 4,4′-diaminodiphenylsulfone, 3,3′-diaminodiphenylsulfide, 3,4′-diaminodiphenylsulfide, 4,4′-diaminodiphenylsulfide, m-phenylenediamine, p-phenylenediamine, 1,4-bis(4-aminophenoxy)benzene, 9,9-bis(4-aminophenyl)fluorine or a diamine having the structure shown below, and the like are preferable. Two or more kinds of these may be used.

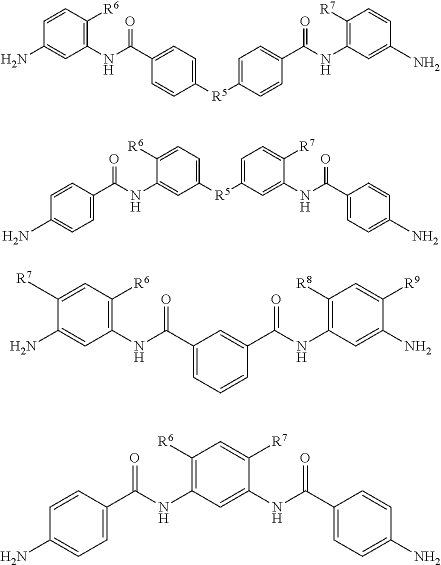

R⁵ represents an oxygen atom, C(CF₃)₂, C(CH₃)₂ or SO₂. R⁶ to R⁹ each represents a hydrogen atom, a hydroxyl group or a thiol group.

Furthermore, in order to improve adhesiveness to a substrate, an aliphatic group having a siloxane structure on R¹ or R² may be copolymerized to the extent that the heat-resistance is not lowered. Specific examples may include those obtained by copolymerizing 1 mol % to 10 mol % of bis(3-aminopropyl)tetramethyldisiloxane, bis(p-aminophenyl)octamethylpentasiloxane or the like as a diamine component, and the like.

In the above-mentioned formula (I-1), R³ and R⁴ each represents a carboxyl group, a phenolic hydroxyl group, a sulfonic acid group or a thiol group. Each of a and b represents an integer of 0 to 10. a and b are preferably 0 from the viewpoint of the stability of the obtained radiation-sensitive resin composition, whereas a and b are preferably 1 or more from the viewpoint of the solubility in the alkali aqueous solution.

By adjusting the amounts of the alkali-soluble groups of R³ and R⁴, the dissolution velocity in the alkali aqueous solution is changed, and thus a radiation-sensitive resin composition having a suitable dissolution velocity can be obtained by this adjustment.

In the case where the above-mentioned R³ and R⁴ are both phenolic hydroxyl groups, in order to adjust the dissolution velocity in a 2.38 mass % aqueous solution of tetramethylammonium hydroxide (TMAH) to a more suitable range, it is preferable that the polyimide resin (a) contains the phenolic hydroxyl group in an amount of 2 mol to 4 mol in 1 kg of (a). By adjusting the amount of the phenolic hydroxyl groups to this range, a radiation-sensitive resin composition having higher sensitivity and higher contrast can be obtained.

Furthermore, it is preferable that the polyimide having the constitutional unit represented by the above-mentioned formula (I-1) has an alkali-soluble group at the terminal of the main chain. Such polyimide has high alkali-solubility. Specific examples of the alkali-soluble group may include a carboxyl group, a phenolic hydroxyl group, a sulfonic acid group and a thiol group, and the like. The alkali-soluble group can be introduced into the terminal of the main chain by providing the alkali-soluble group to an end-capping agent. As the end-capping agent, a monoamine, an acid anhydride, a monocarboxylic acid, a monoacid chloride compound, a monoactive ester compound and the like can be used.

As the monoamine used as the end-capping agent, 5-amino-8-hydroxyquinoline, 1-hydroxy-7-aminonaphthalene, 1-hydroxy-6-aminonaphthalene, 1-hydroxy-5-aminonaphthalene, 1-hydroxy-4-aminonaphthalene, 2-hydroxy-7-aminonaphthalene, 2-hydroxy-6-aminonaphthalene, 2-hydroxy-5-aminonaphthalene, 1-carboxy-7-aminonaphthalene, 1-carboxy-6-aminonaphthalene, 1-carboxy-5-aminonaphthalene, 2-carboxy-7-aminonaphthalene, 2-carboxy-6-aminonaphthalene, 2-carboxy-5-aminonaphthalene, 2-aminobenzoic acid, 3-aminobenzoic acid, 4-aminobenzoic acid, 4-aminosalicylic acid, 5-aminosalicylic acid, 6-aminosalicylic acid, 2-aminobenzenesulfonic acid, 3-aminobenzenesulfonic acid, 4-aminobenzenesulfonic acid, 3-amino-4,6-dihydroxypyrimidine, 2-aminophenol, 3-aminophenol, 4-aminophenol, 2-aminothiophenol, 3-aminothiophenol, 4-aminothiophenol and the like are preferable. Two or more kinds of these may be used.

As the acid anhydride, monocarboxylic acid, monoacid chloride compound and monoactive ester compound used as the end-capping agent, acid anhydrides such as phthalic anhydride, maleic anhydride, nadic anhydride, cyclohexanedicarboxylic anhydride and 3-hydroxyphthalic anhydride, monocarboxylic acids such as 3-carboxyphenol, 4-carboxyphenol, 3-carboxythiophenol, 4-carboxythiophenol, 1-hydroxy-7-carboxynaphthalene, 1-hydroxy-6-carboxynaphthalene, 1-hydroxy-5-carboxynaphthalene, 1-mercapto-7-carboxynaphthalene, 1-mercapto-6-carboxynaphthalene, 1-mercapto-5-carboxy naphthalene, 3-carboxybenzenesulfonic acid and 4-carboxybenzenesulfonic acid, and monoacid chloride compounds formed by acid-chlorinating the carboxyl groups of these compounds, monoacid chloride compounds formed by acid-chlorinating only one of the carboxylic group of dicarboxylic acids such as telephthalic acid, phthalic acid, maleic acid, cyclohexanedicarboxylic acid, 1,5-dicarboxynaphthalene, 1,6-dicarboxynaphthalene, 1,7-dicarboxynaphthalene and 2,6-dicarboxynaphthalene, active ester compounds obtained by a reaction of a monoacid chloride compound with N-hydroxybenzotriazole or N-hydroxy-5-norbornene-2,3-dicarboxylmide, and the like are preferable. Two or more kinds of these may be used.

The introduction ratio of the monoamine used for the end-capping agent is preferably 0.1 mol % or more, specifically preferably 5 mol % or more, and preferably 60 mol % or less, specifically preferably 50 mol % or less, with respect to the whole amine components. The introduction ratio of the acid anhydride, monocarboxylic acid, monoacid chloride compound or monoactive ester compound used as the end-capping agent is preferably 0.1 mol % or more, specifically preferably 5 mol % or more, and preferably 100 mol % or less, specifically preferably 90 mol % or less, with respect to the diamine components. Plural different terminal groups may be introduced by reacting plural end-capping agents.

The repeating number of the constitutional unit in the polyimide having the constitutional unit represented by the above-mentioned formula (I-1) is preferably 3 or more, more preferably 5 or more, and preferably 200 or less, more preferably 100 or less. In this range, use of the photosensitive resin composition of the present invention in a thick film is possible.

In the present exemplary embodiment, the preferable polyimide resin may be formed of only the constitutional unit represented by the above-mentioned formula (I-1), or may be a copolymer or a mixture with other constitutional unit (s). In such case, it is preferable to contain the constitutional unit represented by the above-mentioned formula (I-1) by 10 mass % or more of the entirety of the polyimide resin. When the constitutional unit is 10 mass % or more, it is preferable for the preparation of a thick film since shrinking during thermal curing can be suppressed. It is preferable to select the kind and amount of the constitutional unit used for the copolymerization or mixing to the extent that the heat-resistance of the polyimide obtained by a final heating treatment is not lost. Examples may include benzoxazole, benzimidazole, benzothiazole and the like. These constitutional units are preferably 70 mass % or less in the polyimide resin.

In the present exemplary embodiment, a preferable polyimide resin can be synthesized by utilizing, for example, a method including obtaining a polyimide precursor by using a known method, and imidating the polyimide precursor by using a known imidation reaction process. As a known method for the synthesis of the polyimide precursor, the polyimide precursor can be obtained by reacting an amine component and an acid component by substituting apart of a diamine with a monoamine, which is an end-capping agent, or by substituting a part of an acid dianhydride with a monocarboxylic acid, an acid anhydride, a monoacid chloride compound or a monoactive ester compound, which is an end-capping agent. Examples include a method including reacting a tetracarboxylic dianhydride and a diamine compound (partially substituted with a monoamine) in a low temperature, a method including reacting a tetracarboxylic dianhydride (partially substituted with an acid anhydride, a monoacid chloride compound or a monoactive ester compound) with a diamine compound in a low temperature, a method including obtaining a diester from a tetracarboxylic dianhydride and an alcohol, and then reacting the diester with a diamine (partially substituted with a monoamine) in the presence of a condensation agent, a method including obtaining a diester from a tetracarboxylic dianhydride and an alcohol, and then acid-chlorinating the residual dicarboxylic acid and reacting with a diamine (partially substituted with a monoamine), and the like.

Furthermore, the imidation ratio of the polyimide resin can be easily obtained by, for example, the following method. First, an infrared absorption spectrum of the polymer is measured, and the presence of the absorption peak of the imide structure derived from the polyimide (around 1,780 cm⁻¹ and around 1,377 cm⁻¹) is confirmed. Next, the polymer is heat-treated at 350° C. for 1 hour, an infrared absorption spectrum is measured, and the content of the imide group in the polymer before the heat treatment is calculated by comparing the peak strengths around 1,377 cm⁻¹ to thereby obtain the imidation ratio.

In the present exemplary embodiment, the imidation ratio of the polyimide resin is preferably 80% or more from the viewpoints of chemical resistance and a high residual shrink film ratio.

Furthermore, the end-capping agent that is introduced in the preferable polyimide resin in the present exemplary embodiment can be easily detected by the following method. For example, the end-capping agent used in the present invention can be easily detected by dissolving the polyimide in which the end-capping agent has been introduced in an acidic solution, decomposing the polyimide into an amine component and an acid anhydride component, which are the constitutional units of the polyimide, and measuring the components by gas chromatography (GC) or an NMR measurement. Alternatively, it is also possible to easily detect the end-capping agent by directly measuring the polymer component in which the end-capping agent has been introduced by pyrolysis gas chromatograph (PGC) or an infrared spectrum and a ¹³C-NMR spectrum.

### [Polysiloxane]

The polysiloxane that is preferable as the resin for use in the radiation-sensitive resin composition of the present exemplary embodiment is a polysiloxane having a radical reactive functional group. In the case where the polysiloxane is a polysiloxane having a radical reactive functional group, the polysiloxane is not specifically limited as long as it has a radical reactive functional group on the main chain or side chain of a polymer of a compound having a siloxane bond. In such case, the polysiloxane can be cured by radical polymerization, and thus it is possible to suppress curing shrinkage to the minimum. Examples of the radical reactive functional group may include unsaturated organic groups such as a vinyl group, an α-methylvinyl group, an acryloyl group, a methacryloyl group and a styryl group. Among these, groups having an acryloyl group or a methacryloyl group are preferable since a curing reaction smoothly proceeds.

The polysiloxane that is preferable in the present exemplary embodiment is preferably a hydrolysis condensate of a hydrolysable silane compound. The hydrolysable silane compound that constitutes the polysiloxane is preferably a hydrolysable silane compound containing (s1) a hydrolysable silane compound represented by the following formula (S-1) (hereinafter also referred to as “compound (s1)”), and (s2) a hydrolysable silane compound represented by the following formula (S-2) (hereinafter also referred to as “compound (s2)”).

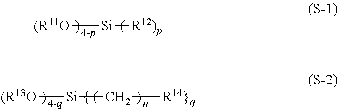

In the above-mentioned formula (S-1), R¹¹ is an alkyl group having 1 to 6 carbon atom(s). R¹² is an organic group containing a radical reactive functional group. p is an integer of 1 to 3. However, in the case where plural numbers of R¹¹s and R¹²s are present, the plural R¹¹s and R¹²s are each independent.

In the above-mentioned formula (S-2), R¹³ is an alkyl group having 1 to 6 carbon atom(s). R¹⁴ is a hydrogen atom, an alkyl group having 1 to 20 carbon atom(s), a fluorinated alkyl group having 1 to 20 carbon atom(s), a phenyl group, a tolyl group, a naphthyl group, an epoxy group, an amino group or an isocyanate group. n is an integer of 0 to 20. Q is an integer of 0 to 3. However, in the case where plural numbers of R¹³s and R¹⁴s are present, the plural R¹³s and R¹⁴s are each independent.

In the present invention, the “hydrolysable silane compound” generally refers to a compound having a group that can generate a silanol group or a group that can generate a siloxane condensate by hydrolysis by being heated within the temperature range of room temperature (about 25° C.) to about 100° C. in the co-presence of excess water without a catalyst. In the hydrolysis reactions of the hydrolysable silane compounds represented by the above-mentioned formula (S-1) and the above-mentioned formula (S-2), a part of the hydrolysable groups may remain in an unhydrolyzed state in the generated polysiloxane. As used herein, the “hydrolysable group” refers to a group that can generate a silanol group or a group that can form a siloxane condensate by the above-mentioned hydrolysis. Furthermore, in a part of the hydrolysable silane compound in the radiation-sensitive resin composition, a part of or the entirety of the hydrolysable groups in the molecule may remain in an unhydrolyzed state, and in a state of a monomer without condensing with the other hydrolysable silane compound. The “hydrolysis condensate” means a hydrolysis condensate in which a part of the silanol groups in the hydrolyzed silane compound are condensed. Hereinafter compound (s1) and compound (s2) will be mentioned in detail.

[Compound (s1)]

In the above-mentioned formula (S-1), R¹¹ is an alkyl group having 1 to 6 carbon atom(s). R¹² is an organic group containing a radical reactive functional group. p is an integer of 1 to 3. However, in the case where plural R¹¹s and R¹²s are present, the plural R¹¹s and R¹²s are each independent.

Examples of the alkyl group having 1 to 6 carbon atom(s), which is the above-mentioned R¹¹, may include a methyl group, an ethyl group, an n-propyl group, an i-propyl group, a butyl group and the like. Among these, a methyl group and an ethyl group are preferable in view of easiness of hydrolysis. As the above-mentioned p, 1 or 2 is preferable, and 1 is more preferable from the viewpoint of the progress of the hydrolysis condensation reaction.

Examples of the organic group having a radical reactive functional group may include a linear, branched or cyclic alkyl group having 1 to 12 carbon atom(s), an aryl group having 6 to 12 carbon atoms, an aralkyl group having 7 to 12 carbon atoms and the like, in which one or more hydrogen atom(s) is/are substituted with the above-mentioned radical reactive functional group(s). When plural R¹²s are present in the same molecule, these are each independent. Furthermore, the organic group represented by R¹² may have a heteroatom. Examples of such organic group may include an ether group, an ester group, a sulfide group and the like.

Examples of compound (s1) in the case where p=1 may include trialkoxysilane compounds such as vinyltrimethoxysilane, vinyltriethoxysilane, vinyltripropoxysilane, o-styryltrimethoxysilane, o-styryltriethoxysilane, m-styryltrimethoxysilane, m-styryltriethoxysilane, p-styryltrimethoxysilane, p-styryltriethoxysilane, allyltrimethoxysilane, allyltriethoxysilane, methacryloxytrimethoxysilane, methacryloxytriethoxysilane, methacryloxytripropoxysilane, acryloxytrimethoxysilane, acryloxytriethoxysilane, acryloxytripropoxysilane, 2-methacryloxyethyltrimethoxysilane, 2-methacryloxyethyltriethoxysilane, 2-methacryloxyethyltripropoxysilane, 3-methacryloxypropyltrimethoxysilane, 3-methacryloxypropyltriethoxysilane, 3-methacryloxypropyltripropoxysilane, 2-acryloxyethyltrimethoxysilane, 2-acryloxyethyltriethoxysilane, 2-acryloxyethyltripropoxysilane, 3-acryloxypropyltrimethoxysilane, 3-acryloxypropyltriethoxysilane, 3-acryloxypropyltripropoxysilane, 3-methacryloxypropyltrimethoxysilane, 3-methacryloxypropyltriethoxysilane, 3-methacryloxypropyltripropoxysilane, trifluoropropyltrimethoxysilane, trifluoropropyltriethoxysilane, trifluorobutyltrimethoxysilane and 3-(trimethoxysilyl)propylsuccinic anhydride.

Examples of compound (s1) in the case where p=2 may include dialkoxysilane compounds such as vinylmethyldimethoxysilane, vinylmethyldiethoxysilane, vinylphenyldimethoxysilane, vinylphenyldiethoxysilane, allylmethyldimethoxysilane, allylmethyldiethoxysilane and phenyltrifluoropropyldimethoxysilane.

Examples of compound (s1) in the case where p=3 may include monoalkoxysilane compounds such as allyldimethylmethoxysilane, allyldimethylethoxysilane, divinylmethylmethoxysilane, divinylmethylethoxysilane, 3-methacryloxypropyldimethylmethoxysilane, 3-acryloxypropyldimethylmethoxysilane, 3-methacryloxypropyldiphenylmethoxysilane, 3-acryloxypropyldiphenylmethoxysilane, 3,3′-dimethacryloxypropyldimethoxysilane, 3,3′-diacryloxypropyldimethoxysilane, 3,3′,3″-trimethacryloxypropylmethoxysilane, 3,3′,3″-triacryloxypropylmethoxysilane and dimethyltrifluoropropylmethoxysilane.

Among these compounds (s1), vinyltrimethoxysilane, p-styryltriethoxysilane, 3-methacryloxypropyltrimethoxysilane, 3-acryloxypropyltrimethoxysilane, 3-methacryloxypropyltriethoxysilane, 3-acryloxypropyltriethoxysilane and 3-(trimethoxysilyl)propylsuccinic anhydride are preferable since scratch resistance and the like can be attained at high levels and the condensation reactivity is increased.

[Compound (s2)]

In the above-mentioned formula (S-2), R¹³ is an alkyl group having 1 to 6 carbon atom(s). R¹⁴ is a hydrogen atom, an alkyl group having 1 to 20 carbon atom(s), a fluorinated alkyl group having 1 to 20 carbon atom(s), a phenyl group, a tolyl group, a naphthyl group, an epoxy group, an amino group or an isocyanate group. n is an integer of 0 to 20. q is an integer of 0 to 3. However, in the case where plural R¹³s and R¹⁴s are present, the plural R¹³s and R¹⁴s are each independent.

Examples of the alkyl group having 1 to 6 carbon atom(s), which is the above-mentioned R¹³, may include a methyl group, an ethyl group, an n-propyl group, an i-propyl group, a butyl group and the like. Among these, a methyl group and an ethyl group are preferable from the viewpoint of easiness of hydrolysis. As the above-mentioned q, 1 or 2 is preferable, and 1 is more preferable from the viewpoint of the progress of the hydrolysis condensation reaction.

In the case where the above-mentioned R¹⁴ is the above-mentioned alkyl group having 1 to 20 carbon atom(s), examples of the alkyl group may include a methyl group, an ethyl group, an n-propyl group, an i-propyl group, an n-butyl group, a sec-butyl group, a tert-butyl group, an n-pentyl group, a 3-methylbutyl group, a 2-methylbutyl group, a 1-methylbutyl group, a 2,2-dimethylpropyl group, an n-hexyl group, a 4-methylpentyl group, a 3-methylpentyl group, a 2-methylpentyl group, a 1-methylpentyl group, a 3,3-dimethylbutyl group, a 2,3-dimethylbutyl group, a 1,3-dimethylbutyl group, a 2,2-dimethylbutyl group, a 1,2-dimethylbutyl group, a 1,1-dimethylbutyl group, an n-heptyl group, a 5-methylhexyl group, a 4-methylhexyl group, a 3-methylhexyl group, a 2-methylhexyl group, a 1-methylhexyl group, a 4,4-dimethylpentyl group, a 3,4-dimethylpentyl group, a 2,4-dimethylpentyl group, a 1,4-dimethylpentyl group, a 3,3-dimethylpentyl group, a 2,3-dimethylpentyl group, a 1,3-dimethylpentyl group, a 2,2-dimethylpentyl group, a 1,2-dimethylpentyl group, a 1,1-dimethylpentyl group, a 2,3,3-trimethylbutyl group, a 1,3,3-trimethylbutyl group, a 1,2,3-trimethylbutyl group, an n-octyl group, a 6-methylheptyl group, a 5-methylheptyl group, a 4-methylheptyl group, a 3-methylheptyl group, a 2-methylheptyl group, a 1-methylheptyl group, a 2-ethylhexyl group, an n-nonanyl group, an n-decyl group, an n-undecyl group, an n-dodecyl group, an n-tridecyl group, an n-tetradecyl group, an n-heptadecyl group, an n-hexadecyl group, an n-heptadecyl group, an n-octadecyl group, an n-nonadecyl group and the like. An alkyl group having 1 to 10 carbon atom(s) is preferable, and an alkyl group having 1 to 3 carbon atom(s) is more preferable.

Examples of compound (s2) in the case where q=0 may include silane compounds substituted with four hydrolysable groups such as tetramethoxysilane, tetraethoxysilane, tetrabutoxysilane, tetra-n-propoxysilane and tetra-i-propoxysilane.

Examples of compound (s2) in the case where q=1 may include silane compounds substituted with one non-hydrolysable group and three hydrolysable groups such as methyltrimethoxysilane, methyltriethoxysilane, methyltri-i-propoxysilane, methyltributoxysilane, ethyltrimethoxysilane, ethyltriethoxysilane, ethyltri-i-propoxysilane, ethyltributoxysilane, butyltrimethoxysilane, phenyltrimethoxysilane, tolyltrimethoxysilane, naphthyltrimethoxysilane, phenyltriethoxysilane, naphthyltriethoxysilane, aminotrimethoxysilane, aminotriethoxysilane, 2-(3,4-epoxycyclohexyl)ethyltrimethoxysilane, γ-glycidoxypropyltrimethoxysilane, 3-isocyanopropyltrimethoxysilane, 3-isocyanopropyltriethoxysilane o-tolyltrimethoxysilane, m-tolyltrimethoxysilane p-tolyltrimethoxysilane and the like.

Examples of compound (s2) in the case where q=2 may include silane compounds substituted with two non-hydrolysable groups and two hydrolysable groups such as dimethyldimethoxysilane, diphenyldimethoxysilane, ditolyldimethoxysilane and dibutyldimethoxysilane.

Examples of compound (s2) in the case where q=3 may include silane compounds substituted with three non-hydrolysable groups and one hydrolysable group such as trimethylmethoxysilane, triphenylmethoxysilane, tritolylmethoxysilane and tributylmethoxysilane.

Among these compounds (s2), the silane compounds substituted with four hydrolysable groups, and the silane compounds substituted with one non-hydrolysable group and three hydrolysable groups are preferable, and the silane compounds substituted with one non-hydrolysable group and three hydrolysable groups are more preferable. Examples of specifically preferable hydrolysable silane compounds may include tetraethoxysilane, methyltrimethoxysilane, methyltriethoxysilane, methyltri-i-propoxysilane, methyltributoxysilane, phenyltrimethoxysilane, tolyltrimethoxysilane, ethyltrimethoxysilane, ethyltriethoxysilane, ethyltriisopropoxysilane, ethyltributoxysilane, butyltrimethoxysilane, γ-glycidoxypropyltrimethoxysilane, naphthyltrimethoxysilane, γ-aminopropyltrimethoxysilane and γ-isocyanatepropyltrimethoxysilane. Such hydrolysable silane compounds may be used alone or by combining two or more.

With respect to the mixing ratio of the above-mentioned compound (s1) and compound (s2), it is desirable that compound (s1) exceeds 5 mol %. In the case where compound (s1) is 5 mol % or less, the exposure sensitivity during formation of a protective film as a cured film is low, and the scratch resistance and the like of the obtained protective film tend to be decreased.

[Hydrolysis Condensation of Compound (s1) and Compound (s2)]

Although the condition for the hydrolysis condensation of the above-mentioned compound (s1) and compound (s2) is not specifically limited as long as at least apart of compound (s1) and compound (s2) is hydrolyzed to convert the hydrolysable group to a silanol group to thereby cause a condensation reaction, for example, the condensation reaction can be carry out as follows.

As the water that is subjected to the hydrolysis condensation reaction, it is preferable to use water purified by a method such as a reverse osmosis membrane treatment, an ion-exchange treatment and distillation. By using such purified water, side reactions can be suppressed to thereby improve the reactivity of the hydrolysis. The use amount of the water is preferably 0.1 mol to 3 mol, more preferably 0.3 mol to 2 mol, specifically preferably 0.5 mol to 1.5 mol with respect to 1 mol of the total amount of the hydrolysable groups of the above-mentioned compound (s1) and compound (s2). By using such amount of water, the reaction velocity of the hydrolysis condensation can be optimized.

Examples of the solvent that is subjected to the hydrolysis condensation may include alcohols, ethers, glycol ethers, ethylene glycol alkyl ether acetates, diethylene glycol alkyl ethers, propylene glycol monoalkyl ethers, propylene glycol monoalkyl ether acetates, propylene glycol monoalkyl ether propionates, aromatic hydrocarbons, ketones, other esters and the like. These solvents can be used alone or by combining two or more.

Among these solvents, ethylene glycol alkyl ether acetates, diethylene glycol alkyl ethers, propylene glycol monoalkyl ethers, propylene glycol monoalkyl ether acetates, butyl methoxyacetate are preferable, and diethylene glycol dimethyl ether, diethylene glycol ethyl methyl ether, propylene glycol monomethyl ether acetate, propylene glycol monomethyl ether and butyl methoxyacetate are specifically preferable.

The hydrolysis condensation reaction is preferably conducted in the presence of a catalyst such as acid catalysts (for example, hydrochloric acid, sulfuric acid, nitric acid, formic acid, oxalic acid, acetic acid, trifluoroacetic acid, trifluoromethanesulfonic acid, phosphoric acid, acidic ion-exchange resins, various Lewis acids and the like), base catalysts (for example, ammonia, primary amines, secondary amines, tertiary amines, nitrogen-containing compounds such as pyridine; basic ion-exchange resins; hydroxides such as sodium hydroxide; carbonates such as potassium carbonate; carboxylates such as sodium acetate; various Lewis bases and the like) or alkoxides (for example, zirconium alkoxides, titanium alkoxides, aluminum alkoxides and the like). For example, as the aluminum alkoxide, tri-i-propoxy aluminum can be used. The use amount of the catalyst is preferably 0.2 mol or less, more preferably 0.00001 mol to 0.1 mol with respect to 1 mol of the monomer of the hydrolysable silane compound, from the viewpoint of the promotion of the hydrolysis condensation reaction.

The above-mentioned hydrolysis condensate has a weight average molecular weight in terms of polystyrene (hereinafter referred to as “Mw”) by GPC (gel permeation chromatography) of preferably 500 to 10,000, more preferably 1,000 to 5,000. By adjusting Mw to 500 or more, the film formability of the radiation-sensitive resin composition of the present exemplary embodiment can be improved. On the other hand, by adjusting Mw to 10,000 or less, lowering in the developability of the radiation-sensitive resin composition can be prevented.

The above-mentioned hydrolysis condensate has a number average molecular weight in terms of polystyrene (hereinafter referred to as “Mn”) by GPC of preferably 300 to 5,000, more preferably 500 to 3,000. By adjusting Mn of the polysiloxane to the above-mentioned range, the curing reactivity during the curing of a coating of the radiation-sensitive resin composition of the present exemplary embodiment can be improved.

The above-mentioned hydrolysis condensate has a molecular weight distribution “Mw/Mn” of preferably 3.0 or less, more preferably 2.6 or less. By adjusting Mw/Mn of the hydrolysis condensate of the compound (s1) and compound (s2) to 3.0 or less, the developability of the obtained protective film can be increased. The radiation-sensitive resin composition containing the polysiloxane causes small residue of developing during developing, and thus a desired pattern shape can be easily formed.

### [Novolak Resin]

The novolak resin, which is preferable as the resin for use in the radiation-sensitive resin composition of the present exemplary embodiment, can be obtained by polycondensation of a phenol with an aldehyde such as formalin by a known method.

Examples of the phenol for obtaining a preferable novolak resin in the present exemplary embodiment may include phenol, p-cresol, m-cresol, o-cresol, 2,3-dimethylphenol, 2,4-dimethylphenol, 2,5-dimethylphenol, 2,6-dimethylphenol, 3,4-dimethylphenol, 3,5-dimethylphenol, 2,3,4-trimethylphenol, 2,3,5-trimethylphenol, 3,4,5-trimethylphenol, 2,4,5-trimethylphenol, methylenebisphenol, methylenebis p-cresol, resorcin, catechol, 2-methylresorcin, 4-methylresorcin, o-chlorophenol, m-chlorophenol, p-chlorophenol, 2,3-dichlorophenol, m-methoxyphenol, p-methoxyphenol, p-butoxyphenol, o-ethylphenol, m-ethylphenol, p-ethylphenol, 2,3-diethylphenol, 2,5-diethylphenol, p-isopropylphenol, α-naphthol, β-naphthol and the like. Two or more kinds of these may be used.

Furthermore, examples of the aldehyde for obtaining a preferable novolak resin in the present exemplary embodiment may include formalin, as well as paraformaldehyde, acetaldehyde, benzaldehyde, hydroxybenzaldehyde, chloroacetaldehyde and the like. Two or more kinds of these may be used.

The novolak resin, which is the resin for use in the radiation-sensitive resin composition of the present exemplary embodiment, has a weight average molecular weight (Mw) in terms of polystyrene by GPC of preferably 2,000 to 50,000, more preferably 3,000 to 40,000.

### [Compound Having Quinonediazide Structure]

The radiation-sensitive resin composition of the present exemplary embodiment contains a compound having a quinonediazide structure as an essential component together with the above-mentioned resin. Therefore, the radiation-sensitive resin composition of the present exemplary embodiment can be used as a positive-type radiation-sensitive resin composition. Furthermore, a light shielding property can be imparted to a formed protective film. In addition, it is also possible to adjust the transparency of the formed protective film by a photobleach performance.

The compound having a quinonediazide structure is a quinonediazide compound that generates a carboxylic acid by irradiation of radioactive ray. As the compound having a quinonediazide structure, a condensate of a phenolic compound or an alcoholic compound (hereinafter referred to as “scaffold”) and a 1,2-naphthoquinonediazide sulfonic acid halide can be used.

Examples of the above-mentioned scaffold may include trihydroxybenzophenones, tetrahydroxybenzophenones, pentahydroxybenzophenones, hexahydroxybenzophenones, (polyhydroxyphenyl)alkanes, other scaffolds and the like.

Examples of the trihydroxybenzophenones may include 2,3,4-trihydroxybenzophenone, 2,4,6-trihydroxybenzophenone and the like.

Examples of the tetrahydroxybenzophenones may include 2,2′,4,4′-tetrahydroxybenzophenone, 2,3,4,3′-tetrahydroxybenzophenone, 2,3,4,4′-tetrahydroxybenzophenone, 2,3,4,2′-tetrahydroxy-4′-methylbenzophenone, 2,3,4,4′-tetrahydroxy-3′-methoxybenzophenone and the like.

Examples of the pentahydroxybenzophenones may include 2,3,4,2′,6′-pentahydroxybenzophenone and the like.

Examples of the hexahydroxybenzophenones may include 2,4,6,3′,4′,5′-hexahydroxybenzophenone, 3,4,5,3′,4′,5′-hexahydroxybenzophenone and the like.

Examples of the (polyhydroxyphenyl)alkanes may include bis(2,4-dihydroxyphenyl)methane, bis(p-hydroxyphenyl)methane, tris(p-hydroxyphenyl)methane, 1,1,1-tris(p-hydroxyphenyl)ethane, bis(2,3,4-trihydroxyphenyl)methane, 2,2-bis(2,3,4-trihydroxyphenyl)propane, 1,1,3-tris(2,5-dimethyl-4-hydroxyphenyl)-3-phenylpropane, 4,4′-[1-{4-(1-t4-hydroxyphenyl]-1-methylethyl)phenyl}ethylidene]bisphenol, bis(2,5-dimethyl-4-hydroxyphenyl)-2-hydroxyphenylmethane, 3,3,3′,3′-tetramethyl-1,1′-spirobiindene-5,6,7,5′,6′,7′-hexanol, 2,2,4-trimethyl-7,2′,4′-trihydroxyflavan and the like.

Examples of the other scaffolds may include 2-methyl-2-(2,4-dihydroxyphenyl)-4-(4-hydroxyphenyl)-7-hydr oxychroman, 1-[1-[3-(1-[4-hydroxyphenyl]-1-methylethyl)-4,6-dihydroxyphenyl]-1-methylethyl]-3-[1-[3-(1-[4-hydroxyphenyl]-1-methylethyl)-4,6-dihydroxyphenyl]-1-methylethyl]benzene, 4,6-bis{1-(4-hydroxyphenyl)-1-methylethyl}-1,3-dihydroxybenzene and the like.

Among these scaffolds, 2,3,4,4′-tetrahydroxybenzophenone, 1,1,1-tris(p-hydroxyphenyl)ethane and 4,4′-[1-{4-(1-[4-hydroxyphenyl]-1-methylethyl)phenyl}ethylidene]bisphenol are preferably used.

As the 1,2-naphthoquinonediazide sulfonic acid halides, 1,2-naphthoquinonediazide sulfonic acid chlorides are preferable. Examples of the 1,2-naphthoquinonediazide sulfonic acid chlorides may include 1,2-naphthoquinonediazide-4-sulfonic acid chloride, 1,2-naphthoquinonediazide-5-sulfonic acid chloride and the like. Among these, 1,2-naphthoquinonediazide-5-sulfonic acid chloride is more preferable.

In the condensation reaction of the phenolic compound or alcoholic compound (scaffold) and the 1,2-naphthoquinonediazide sulfonic acid halide, a 1,2-naphthoquinonediazide sulfonic acid halide that corresponds to preferably 30 mol % to 85 mol %, more preferably 50 mol % to 70 mol % with respect to the number of the OH groups in the phenolic compound or alcoholic compound can be used. The condensation reaction can be carried out by a known method.

Furthermore, as the compound having a quinonediazide structure, 1,2-naphthoquinonediazide sulfonic acid amides in which the ester bonds in the scaffolds exemplified above are changed to amide bonds such as 2,3,4-triaminobenzophenone-1,2-naphthoquinonediazide-4-sulfonic acid amide are also preferably used.

These compounds having a quinonediazide structure can be used alone or by combining two or more. The use rate of the compound having a quinonediazide structure in the radiation-sensitive resin composition of the present exemplary embodiment is preferably 5 parts by mass to 100 parts by mass, more preferably 10 parts by mass to 50 parts by mass with respect to 100 parts by mass of the compound having a quinonediazide structure. By adjusting the use ratio of the compound having a quinonediazide structure to the above-mentioned range, the difference in solubilities in an alkali aqueous solution as a developer between a part irradiated with radioactive ray and an unirradiated part can be increased to thereby improve a patterning performance. Furthermore, the solvent resistance of a protective film obtained by using this radiation-sensitive resin composition can be improved.

### [Ultraviolet Absorber]

The radiation-sensitive resin composition of the present exemplary embodiment contains the above-mentioned resin and compound having a quinonediazide structure as essential components, and can contain a ultraviolet absorber together with those components as necessary. By this way, the radiation-sensitive resin composition of the present exemplary embodiment can impart ultraviolet absorbability to a formed protective film. Furthermore, the effect of ultraviolet in a TFT in an organic EL display element can be decreased.

The ultraviolet absorber is preferably a compound having absorption in the wavelength region of 300 nm to 400 nm. Although the ultraviolet absorber is not specifically limited as long as it has an absorption band in the above-mentioned range, specifically, easily available ultraviolet absorbers such as a benzotriazole-based compound and a benzophenone-based compound having an absorption band in the above-mentioned range are preferably used.

The benzotriazole-based compound is a compound having a structure represented by the following formula (1). The benzophenone-based compound is a compound having a structure represented by the following formula (2).

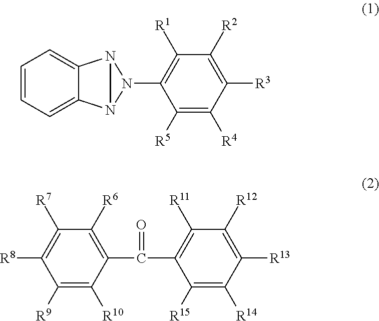

In the above-mentioned formula (1) and the above-mentioned formula (2), R¹ to R¹⁵ each independently represents hydrogen, an alkyl group having 1 to 20 carbon atom(s), an alkoxy group having 1 to 20 carbon atom(s), a benzoyloxy group having 1 to 20 carbon atom(s) or a hydroxyl group.

Specific examples of such benzotriazole-based compound may include 2-(2-hydroxy-5-methylphenyl)-2H-benzotriazole, 2-(3-t-butyl-2-hydroxy-5-methylphenyl)-5-chloro-2H-benzotriazole, 2-(3,5-di-t-pentyl-2-hydroxyphenyl)-2H-benzotriazole, 2-(2-hydroxy-4-octyloxyphenyl)-2H-benzotriazole, 2-(2-hydroxy-5-t-octylphenyl)-2H-benzotriazole and the like. These benzotriazole-based compounds may be used alone or by combining two or more.

Furthermore, specific examples of such benzophenone-based compound may include 2,4-dihydroxybenzophenone, 2-hydroxy-4-methoxybenzophenone, 2-hydroxy-4-methoxybenzophenone-5-sulfonic acid trihydrate, 2-hydroxy-4-octyloxybenzophenone, 4-dodecyloxy-2-hydroxybenzophenone, 4-benzyloxy-2-hydroxybenzophenone, 2,2′4,4′-tetrahydroxybenzophenone, 2,2′-dihydroxy-4,4′-dimethoxybenzophenone and the like. These benzophenone-based compounds may be used alone or by combining two or more.

The use amount of the ultraviolet absorber in the radiation-sensitive resin composition of the present exemplary embodiment is used preferably in the range of 0.01 parts by mass to 30 parts by mass, specifically preferably in the range of 0.1 parts by mass to 20 parts by mass with respect to 100 parts by mass of the resin. When the amount is 0.01 parts by mass or less, the shielding effect of the obtained protective film against ultraviolet ray is poor, whereas when the amount is 30 parts by mass or more, the radiation sensitivity of the radiation-sensitive resin composition of the present exemplary embodiment decreases, and formation of a pattern may be interrupted.

### [Other Components]

The radiation-sensitive resin composition of the present exemplary embodiment contains the resin and the compound having a quinonediazide structure as essential components, and can contain the ultraviolet absorber, and a curing promoter, a thermal acid generator and other optional components.

The curing promoter is a compound that fulfills a function to promote the curing of a film formed by the radiation-sensitive resin composition of the present exemplary embodiment.

Examples of the curing promoter may include at least one compound selected from the group consisting of compounds having an electron-withdrawing group and an amino group in a molecule such as 4,4′-diaminodiphenylsulfone, 2,2-bis(4-aminophenyl)hexafluoropropane, 2,2′-bis(trifluoromethyl)benzidine, ethyl 3-aminobenzenesulfonate, 3,5-bistrifluoromethyl-1,2-diaminobenzene, 4-aminonitrobenzene and N,N-dimethyl-4-nitroaniline, tertiary amine compounds, amide compounds, thiol compounds, block isocyanate compounds and imidazole ring-containing compounds.

The thermal acid generator is a compound capable of releasing an acidic active substance that acts as a catalyst during curing of the resin by applying heat.

The radiation-sensitive resin composition of the present exemplary embodiment can contain other optional components such as a surfactant, a storage stabilizer, an adhesion aid and a heat-resistance improver as necessary to the extent that the effect of the present invention is not deteriorated. These respective optional components may be used alone or by combining two or more.

### <Method for Preparing Radiation-Sensitive Resin Composition>

The radiation-sensitive resin composition of the present exemplary embodiment is prepared by evenly mixing the resin and the compound having a quinonediazide structure. Furthermore, in the case where the ultraviolet absorber, curing promoter and thermal acid generator, or the other optional components that are added as necessary are contained, the composition is prepared by evenly mixing the resin and compound having a quinonediazide structure and those components. This radiation-sensitive resin composition is preferably used in the form of a solution by being dissolved in a suitable solvent. The solvent may be used alone or by mixing two or more solvents.

As the solvent used for the preparation of the radiation-sensitive resin composition of the present exemplary embodiment, a solvent that evenly dissolves the essential components and optional components and does not react with the respective components is used. Examples of such solvent may include alcohols, glycol ethers, ethylene glycol alkyl ether acetates, diethylene glycol monoalkyl ethers, diethylene glycol dialkyl ethers, dipropylene glycol dialkyl ethers, propylene glycol monoalkyl ethers, propylene glycol alkyl ether acetates, propylene glycol monoalkyl ether propionates, ketones, esters and the like.

Although the content of the solvent is not specifically limited, from the viewpoints of the application property, stability and the like of the obtained radiation-sensitive resin composition, an amount that makes the total concentration of the respective components except for the solvent in the radiation-sensitive resin composition 5 mass % to 50 mass % is preferable, and an amount that makes the total concentration 10 mass % to 40 mass % is more preferable. In the case where a solution of the radiation-sensitive resin composition is prepared, a solid content concentration (the components other than the solvent in the composition solution) that corresponds to a value of a desired film thickness or the like is actually preset in the above-mentioned concentration range.

It is preferable to filter the solution-like composition prepared by this way by using a Millipore filter having a pore diameter of about 0.5 μm or the like, and thereafter use the composition for forming the protective film of the present exemplary embodiment.

### <Method for Forming Protective Film>

The protective film of the organic EL display element of the present exemplary embodiment is formed as a cured film, according to a known method, by applying the radiation-sensitive resin composition of the present exemplary embodiment on a substrate on which a TFT, and as necessary, an inorganic insulating film for covering it, and the like have been formed, conducting necessary patterning such as formation of a through-hole, and conducting thermal curing. It is preferable that the formed protective film is constituted by containing the compound having a quinonediazide structure contained in the radiation-sensitive resin composition. In such case, the formed protective film can have a desired light shielding property.

Hereinafter the method for forming the protective film will be explained in more detail.

In the formation of the protective film for a semiconductor element of the present exemplary embodiment, a coating film of the radiation-sensitive resin composition of the present exemplary embodiment is first formed on a substrate. On this substrate, a TFT composed of a gate electrode, a gate insulating film and a semiconductor layer and the like, and the like are formed according to known methods. For example, in the case where the semiconductor layer is a semiconductor layer formed by using an amorphous oxide such as IGZO, it is formed by repeating film-formation of a semiconductor and etching by a photolithographic process on a substrate according to the method described in JP 2006-165529 A or the like.

In the above-mentioned substrate, the radiation-sensitive resin composition of the present exemplary embodiment is applied to the surface on which the TFT and the like have been formed, and prebaking is conducted to allow evaporation of the solvent to thereby form a coating film.

As the method for applying the radiation-sensitive resin composition, for example, suitable methods such as a spray process, a roll coat process, a rotation application process (also referred to as a spin coat process or a spinner process), a slit application process (a slit dye application process), a bar application process and an inkjet application process can be adopted. Among these, the spin coat process or slit application process is preferable from the viewpoint that a film having an even thickness can be formed.

Although the conditions for the above-mentioned prebaking differ depending on the kinds, incorporation ratio and the like of the respective components that constitute the radiation-sensitive resin composition, it is preferable to conduct at a temperature of 70° C. to 120° C.; and although the time differs depending on a heating apparatus such as a hot plate and an oven, it is approximately about 1 minute to 15 minutes.

At least a part of the coating film formed as above is then irradiated with radioactive ray. At this time, in order to irradiate only a part of the coating film, for example, the irradiation is conducted through a photomask having a pattern that corresponds to a desired through-hole and a desired shape.

The radioactive ray used for the irradiation may include visible ray, ultraviolet ray, far ultraviolet ray and the like. Among these, radioactive ray having a wavelength in the range of 200 nm to 550 nm is preferable, and radioactive ray containing ultraviolet ray at 365 nm is more preferable.

The irradiation amount (amount of exposure) of the radioactive ray can be 10 J/m² to 10,000 J/m², preferably 100 J/m² to 5,000 J/m², more preferably 200 J/m² to 3,000 J/m², as a value that is obtained by measuring the intensity of the irradiated radioactive ray at a wavelength of 365 nm by an irradiance meter (OAI model 356, manufactured by Optical Associates Inc.).

Next, the coating film after the radioactive ray irradiation is developed to remove unnecessary parts to thereby give a coating film having a through-hole having a predetermined shape formed thereon.

As the developer for use in the developing, for example, aqueous solutions of inorganic alkalis such as sodium hydroxide, potassium hydroxide and sodium carbonate, quaternary ammonium salts such as tetramethylammonium hydroxide and tetraethylammonium hydroxide, alkaline compounds such as choline, 1,8-diazabiyclo-[5.4.0]-7-undecene and 1,5-diazabiyclo-[4.3.0]-5-nonene can be used. The aqueous solution of the above-mentioned alkaline compound can also be used by adding a suitable amount of a water-soluble organic solvent such as methanol and ethanol. Furthermore, the aqueous solution can also be used by adding a suitable amount of a surfactant as it is, or together with the addition of the above-mentioned water-soluble organic solvent.

The developing method may be any of a puddle process, a dipping process, a shower process, a spray process and the like, and the developing time can be 5 seconds to 300 seconds at an ordinary temperature, preferably about 10 seconds to 180 seconds at an ordinary temperature. Subsequent to the developing treatment, for example, washing with running water is conducted for 30 seconds to 90 seconds, and air drying is conducted by compressed air or compressed nitrogen to thereby give a desired pattern.

Subsequently, the coating on which the through-hole having a predetermined shape has been formed is subjected to curing (also referred to as post-bake) by a suitable heating apparatus such as a hot plate and an oven. By this way, a cured film is formed, and thus the protective film of the present exemplary embodiment can be obtained. The film thickness of the protective film is preferably 1 μm to 6 μm. As mentioned above, the protective film has a through-hole disposed on a desired position, and has a desired shape.

According to the radiation-sensitive resin composition of the present exemplary embodiment, it is preferable to adjust the curing temperature during the post-bake to 100° C. to 250° C. Furthermore, it is also possible to adjust the curing temperature to curing at a low temperature of 200° C. or less depending on the effect of the added curing promoter, and the like. The curing time is preferably adjusted to, for example, 5 minutes to 30 minutes on a hotplate, and is preferably adjusted to 30 minutes to 180 minutes in an oven.

### <Bank>

As mentioned below, the bank of the exemplary embodiment of the present invention can be formed by using the radiation-sensitive resin composition of the present exemplary embodiment, and is preferable as a bank for the organic EL element of the exemplary embodiment of the present invention and can be used as a bank for the above-mentioned the organic EL display element of the present exemplary embodiment. The bank, which is a major constitutional element of the organic EL display element of the present exemplary embodiment, will be explained below.

As mentioned above, the organic EL display element of the present exemplary embodiment has a bank, which is a division wall for defining an arranging area for the organic luminescent layer, on the anode formed on the above-mentioned protective film. The bank can have, for example, a grid-like shape in planar view so as to correspond to respective pixels disposed in a matrix pattern. An organic luminescent layer that emits light in an electric field is disposed in the area defined by this bank. In the organic EL display element of the present exemplary embodiment, the bank is a barrier wall that encompasses the surrounding of the organic luminescent layer to thereby compart the adjacent respective pixels from each other.

Therefore, the bank is required to be capable of defining the arranging area for the organic luminescent layer so that the bank would have a desired thin linewidth and ensure a sufficient surface area of the organic luminescent layer, and even shapes of the organic luminescent layers would be given among the respective pixels. In order to attain such properties, the bank is preferably formed by using a radiation-sensitive resin composition. Furthermore, the bank is required in its formation to prevent intrusion of impurities (mainly moisture) to the organic luminescent layer. Therefore, a radiation-sensitive resin composition that can prevent intrusion of impurities (mainly moisture) to the organic luminescent layer and thus can form a bank in which inhibition of the luminescence of the organic luminescent layer is decreased is required.

Furthermore, it is preferable that the bank is effective for the above-mentioned problem of the effect of light on a conventional organic EL display element.

Therefore, for the formation of the bank of the organic EL display element of the present exemplary embodiment, the radiation-sensitive resin composition of the present exemplary embodiment, which was used for the above-mentioned formation of the protective film of the organic EL display element of the present exemplary embodiment, can be used.

The above-mentioned the radiation-sensitive resin composition of the present exemplary embodiment is constituted by containing a resin and a compound having a quinonediazide structure, and thus can realize patterning with a high resolution of a coating film of the composition to thereby realize a desired shape. Furthermore, the composition can prevent intrusion of impurities (mainly moisture) to the organic luminescent layer and thus can form a bank in which inhibition of the luminescence of the organic luminescent layer is decreased.

In addition, the organic EL display element of the present exemplary embodiment having the above-mentioned bank is capable of light-shielding of the semiconductor layer of the TFT by the effect of the bank containing the compound having a quinonediazide structure. Furthermore, the organic EL display element of the present exemplary embodiment can decrease the lowering in the properties due to the effect of light, by the light-shielding effect of the bank. As mentioned above, such light-shielding function of the bank by containing the compound having a quinonediazide structure is specifically effective for an organic EL display element having a TFT of a semiconductor layer using an amorphous oxide such as IGZO that has a more significant problem in light resistance.

It is sometimes considered to be not preferable that the bank that defines the arranging area for the organic luminescent layer has a light shielding property at this time since there is fear that the efficiency of the luminescence from the organic luminescent layer is decreased.

However, as mentioned above, the organic EL display element of the present exemplary embodiment can preferably control the balance between the light translucency and light shielding property of the bank by using a bank containing a compound having a quinonediazide structure.

Therefore, the bank of the organic EL display element of the present exemplary embodiment contains at least one of the compound having a quinonediazide structure and the compound having an indenecarboxylic acid structure, together with the resin.

As mentioned above, in the organic EL display element of the present exemplary embodiment, the bank thereof shows the above-mentioned inherent effect in addition to the patterning property and the like. Furthermore, the radiation-sensitive resin composition of the present exemplary embodiment, which is used for the formation of the protective film, can be used for the formation of the bank. Therefore, the organic EL display element of the present exemplary embodiment can use a common radiation-sensitive resin composition for the formation of the protective film and bank, and thus it is possible to attain high producibility.

In addition, in the case where the above-mentioned the radiation-sensitive resin composition of the present exemplary embodiment is used for the formation of the bank, it is possible to incorporate a liquid repellent as the other component. As mentioned above, since the bank defines an area to which an ink-like luminescent material composition containing an organic luminescent material is applied, it is preferable that the bank has low wettability. Therefore, the liquid repellent contained in the radiation-sensitive resin composition effectively functions in some cases. Examples of the liquid repellent include fluorine compounds such as vinylidene fluoride, vinyl fluoride and ethylene trifluoride, fluorine-containing polymers and the like.

Next, the formation of the bank of the organic EL display element of the present exemplary embodiment will be explained in more detail.

### <Method for Forming Bank>

The bank can be formed by using the above-mentioned the radiation-sensitive resin composition of the present exemplary embodiment and using a photolithographic process. Alternatively, it is also possible to form by using a printing process. In the case where a photolithographic process is utilized, a coating film of the radiation-sensitive resin composition of the present exemplary embodiment is formed on the above-mentioned substrate having a protective film and an anode formed thereon. As mentioned above, the anode on the protective film is formed of, for example, an electroconductive material such as ITO. The anode can be formed by forming the electroconductive material into a film on the protective film by utilizing a sputtering process or the like, and subjecting the formed film to patterning by etching or the like. Alternatively, it is also possible to form an anode by applying a liquid-like anode-forming material onto the protective film, by inkjet, a dispenser, a relief printing plate, intaglio printing or the like, and drying the applied anode-forming material.

Subsequently, application is conducted by using the radiation-sensitive resin composition of the present exemplary embodiment onto the substrate having the protective film and an anode formed thereon, and the solvent is evaporated by prebaking to thereby form a coating film.

As the method for applying the radiation-sensitive resin composition, for example, suitable methods such as a spray process, a roll coat process, a rotary application process, a slit application process, a bar application process and an inkjet application process can be adopted. Among these, the rotary application process or slit application process is preferable from the viewpoint that a film with an even thickness can be formed.

Although the conditions for the above-mentioned prebake differ depending on the kinds, incorporation ratio and the like of the respective components that constitute the radiation-sensitive resin composition, it is preferable to conduct at a temperature of 70° C. to 120° C., and although the time differs depending on a heating apparatus such as a hot plate and an oven, it is approximately about 1 minute to 15 minutes. The film thickness of the formed coating can be 3 μm to 6 μm as a value after the prebaking.

Subsequently, at least a part of the coating formed as above is irradiated with radioactive ray. At this time, in order to irradiate only a part of the coating, for example, it is preferable to conduct irradiation through a photomask having a pattern corresponding to a desired shape.

Examples of the radioactive ray used for the irradiation may include visible ray, ultraviolet ray, far ultraviolet ray and the like. Among these, radioactive ray having a wavelength in the range of 200 nm to 550 nm is preferable, and radioactive ray containing ultraviolet ray at 365 nm is more preferable.

The amount of irradiation of the radioactive ray (amount of exposure) can be 10 J/m² to 10,000 J/m², preferably 100 J/m² to 5,000 J/m², and more preferably 200 J/m² to 3,000 J/m² as a value that is obtained by measuring the strength of the irradiated radioactive ray at a wavelength of 365 nm by an irradiance meter (OAI model 356, manufactured by Optical Associates Inc.).

Subsequently, a coating formed into a predetermined shape can be obtained by removing unnecessary parts by developing the coating film after irradiation with radioactive ray.

As a developer used for the developing, aqueous solutions of inorganic alkalis such as sodium hydroxide, potassium hydroxide and sodium carbonate, quaternary ammonium salts such as tetramethylammonium hydroxide and tetraethylammonium hydroxide, and alkaline compounds such as choline, 1,8-diazabiyclo-[5.4.0]-7-undecene and 1,5-diazabiyclo-[4.3.0]-5-nonene can be used. The above-mentioned aqueous solutions of the alkaline compounds can also be used by adding water-soluble organic solvents such as methanol and ethanol in a suitable amount. In addition, a surfactant can be used alone or together with the addition of the above-mentioned water-soluble organic solvents, by adding in a suitable amount.

The developing method may be any of a puddle process, a dipping process, a shower process, a spray process and the like, and the developing time can be 5 seconds to 300 seconds at an ordinary temperature, preferably about 10 seconds to 180 seconds at an ordinary temperature. Subsequent to the developing treatment, a desired pattern can be obtained by, for example, conducting washing with flown water for 30 seconds to 90 seconds, and conducting air drying with compressed air or compressed nitrogen.

Subsequently, the coating on which a through-hole having a predetermined shape has been formed is post-baked by a suitable heating apparatus such as a hot plate and an oven. By this way, a cured film is formed, and the bank of the present exemplary embodiment having a desired shape can be obtained.

According to the radiation-sensitive resin composition of the present exemplary embodiment, it is preferable that the curing temperature during the post-baking is adjusted to 100° C. to 250° C. Furthermore, it is also possible to conduct curing at a curing temperature at a low temperature of 200° C. or less depending on the effect of the added curing promoter and the like. The curing time is adjusted to, for example, preferably 5 minutes to 30 minutes on a hot plate, or preferably 30 minutes to 180 minutes in an oven.

The structure and major constitutional elements of the organic EL display element of the present exemplary embodiment have been explained above, and subsequently, the method for the production of the organic EL display element of the present exemplary embodiment will be explained. The preparation of the substrate on which the TFT for the organic EL display element of the present exemplary embodiment has been formed, and the formation of the protective film and bank and the like can follow the above-mentioned methods, and the formation of the organic luminescent layer will be mainly explained below.

### <Method for Producing Organic EL Display Element>

The method for producing the organic EL display element of the present exemplary embodiment includes, as a major step, a step of forming an organic luminescent layer on an area defined by a bank, by using a substrate on which a TFT and the like have been formed, and a protective film and a bank have been formed according to the above-mentioned method.

In this step, an ink-like luminescent material composition containing materials for the organic luminescent layer is applied onto the anode in the area defined by the bank to thereby form the organic luminescent layer. Organic luminescent layers that respectively emit lights of red, green and blue are formed by applying liquid luminescent material compositions each containing an organic luminescent material and a solvent onto areas defined by banks and drying the applied compositions. Examples of the solvent include aromatic-based solvents such as anisole. The means for the application is not specifically limited. Examples of the means for application include methods using inkjet, a dispenser, a nozzle coat, rotary application, intaglio printing, printing using a relief printing plate, and the like. A preferable application means is the inkjet process. Furthermore, the amount of the luminescent material composition fed is preferably 40 pl to 120 pl per one pixel (5,000 μm² to 30,000 μm²).

By applying the liquid-like luminescent material composition containing the organic luminescent material and solvent to the pixel area by an application process such as an inkjet process, the organic luminescent layer can be easily formed without damaging the other materials.

After forming the organic luminescent layer by this step, a cathode is formed on the organic luminescent layer according to a known method such as a deposition process and a sputtering process. Preferably, a passivation film is formed on the cathode according to a known method, and the surface of the substrate on which the organic luminescent layer has been formed is sealed from the upper side by a sealing substrate. The sealing is conducted by, for example, applying a ultraviolet-curable seal material along the outer periphery of the sealing of the sealing substrate, and sticking the substrate on which the organic luminescent layer has been formed and the sealing substrate together in an inert gas atmosphere such as nitrogen gas and argon gas. By this way, the inert gas such as nitrogen gas constitutes a sealing layer, and the organic luminescent layer is enclosed in a closed space under an inert gas atmosphere. Subsequently, the sealing material is cured by irradiating with ultraviolet ray. By this way, the organic EL display element of the present exemplary embodiment can be obtained. The sealing layer can also be a layer of a filler material such as an adhesive.

In the organic EL display element of the present exemplary embodiment produced as above, a through-hole with desired disposition and shape is formed on the protective film, and a desired narrow and even line width and an edge part without backlash are attained on the bank. Consequently, the organic EL display element of the present exemplary embodiment attains excellent control of shapes in the constitutional elements such as the protective film and bank. Furthermore, the organic EL display element of the present exemplary embodiment is an organic EL display element having high luminance and high reliability, and high producibility.

### EXAMPLES

Hereinafter the exemplary embodiments of the present invention will be described in detail based on Examples, but the present invention is not interpreted in a limited way by these Examples.

### Preparation of Radiation-Sensitive Resin Composition

### Synthesis Example 1

### Synthesis of Resin (α-1)

Eight parts by mass of 2,2′-azobis(2,4-dimethylvaleronitrile) and 220 parts by mass of diethylene glycol methyl ethyl ether were charged in a flask equipped with a cooling tube and a stirrer. Subsequently, 15 parts by mass of methacrylic acid, 40 parts by mass of glycidyl methacrylate, 10 parts by mass of hydroxyphenyl methacrylate, 20 parts by mass of methyl methacrylate and 15 parts by mass of N-cyclohexylmaleimide were charged, substitution with nitrogen was conducted, the temperature of the solution was raised to 70° C. while the solution was gently stirred, and polymerization was conducted by retaining the temperature for 5 hours to thereby give a solution containing Resin (α-I) as a copolymer. Resin (α-I), which was a copolymer, had a Mw of 8,000.

### Synthesis Example 2

### Synthesis of Resin (α-II)

Under an airflow of dried nitrogen, 29.30 g (0.08 mol) of bis(3-amino-4-hydroxyphenyl)hexafluoropropane (Central Glass Co., Ltd.), 1.24 g (0.005 mol) of 1,3-bis(3-aminopropyl)tetramethyldisiloxane and 3.27 g (0.03 mol) of 3-aminophenol (Tokyo Chemical Industry Co., Ltd.) as an end-capping agent were dissolved in 80 g of N-methyl-2-pyrrolidone (hereinafter also referred to as NMP). 31.2 g (0.1 mol) of bis(3,4-dicarboxyphenyl)ether dianhydride (Manac Inc.) was added thereto together with 20 g of NMP and reacted at 20° C. for 1 hour and reacted at 50° C. for 4 hours. Thereafter, 15 g of xylene was added, and stirring was conducted at 150° C. for 5 hours while the water was removed together with xylene by an azeotropic means. After the stirring was completed, the solution was put into 3 L of water to give a white precipitation. This precipitation was collected by filtration, washed with water three times and dried in a vacuum drier at 80° C. for 20 hours to give Resin (α-II) as a polymer having a structure represented by the following formula.

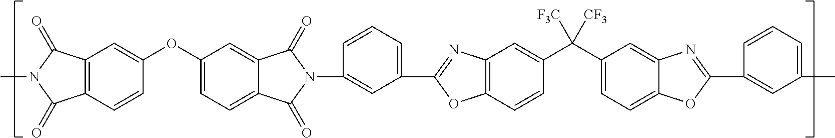

### Synthesis Example 3

### Synthesis of Resin (α-III)

20 parts by mass of propylene glycol monomethyl ether was charged in a container equipped with a stirrer, 70 parts by mass of methyltrimethoxysilane and 30 parts by mass of tolyltrimethoxysilane were charged, and the solution was heated until the solution temperature was 60° C. After the solution temperature reached 60° C., 0.15 parts by mass of phosphoric acid and 19 parts by mass of ion-exchange water were charged and heated to 75° C., and retained for 4 hours. Furthermore, the solution temperature was adjusted to 40° C., and the ion-exchange water and the methanol generated by the hydrolysis condensation were removed by evaporating while retaining this temperature. By this way, a siloxane polymer as a hydrolysis condensate was obtained. Resin (α-III), which was a siloxane polymer, had a Mw of 5,000.

### Example 1

### Preparation of Radiation-sensitive resin composition (β-I)

The solution containing Resin (α-I) of Synthesis Example 1 in an amount corresponding to 100 parts by mass of the copolymer (solid content), and 35 parts by mass of the following compound as a compound having a quinonediazide structure, and 5 parts by mass of 2,2′,4,4′-tetrahydroxybenzophenone as an ultraviolet absorber were mixed, dissolved in diethylene glycol ethyl methyl ether and filtered through a membrane filter having a pore diameter of 0.2 μm to thereby prepare Radiation-sensitive resin composition (β-I).

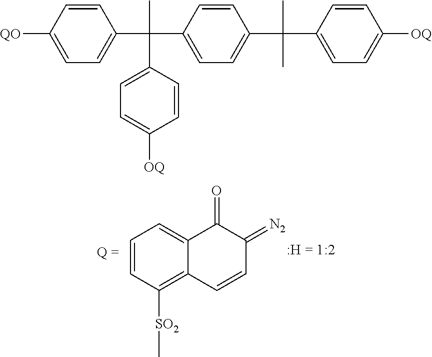

### Example 2

### Preparation of Radiation-Sensitive Resin Composition (β-II)

2 g of a novolak resin (trade name, XPS-4958G, m-cresol/p-cresol ratio=55/45 (weight ratio), Gunei Chemical Industry Co., Ltd.) was added to 8 g of Resin (α-II) of Synthesis Example 2. Furthermore, 2.4 g of a compound represented by the following formula (β1) and 0.6 g of a compound represented by the following formula (β2) were added as thermal crosslinkable compounds that effect a crosslinking reaction by heat, 2 g of a compound having a quinonediazide structure (β3) was added, 0.5 g of 2-(2-hydroxy-5-methylphenyl)-2H-benzotriazole was added as an ultraviolet absorber, these were dissolved by adding γ-butyrolactone as a solvent thereto and then filtered through a membrane filter having a pore size of 0.2 μm to prepare Radiation-sensitive resin composition (β-II).

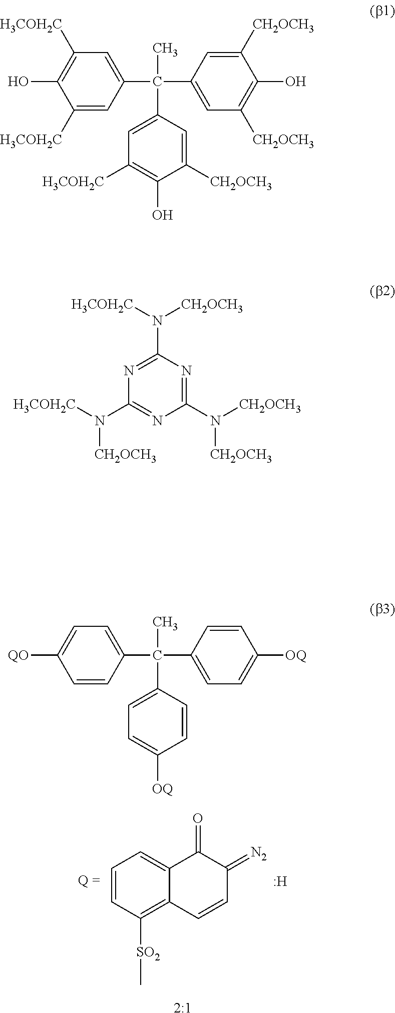

### Example 3

### Preparation of Radioactive Sensitive Resin Composition (β-III)

12 parts by mass of a condensate of 4,4′-[1-[(4-(1-[4-hydroxyphenyl]-1-methylethyl)phenyl]ethyli dene]bisphenol (1.0 mol) and 1,2-naphthoquinonediazide-5-sulfonic acid chloride (3.0 mol) was added as a compound having a quinonediazide structure to a solution containing Resin (α-III), which is the siloxane polymer obtained in Synthesis Example 3 (in an amount corresponding to 100 parts by mass of the siloxane polymer (solid content)), 5 parts by mass of 2,2′,4,4′-tetrahydroxybenzophenone was added as an ultraviolet absorber, andpropyleneglycolmonomethyletherwas added so that the concentration of the solid content was 25 mass % to thereby prepare Radiation-sensitive resin composition (β-III).

### Formation of Cured Film and Evaluation of Radiation Sensitivity

### Example 4

Radiation-sensitive resin composition (β-I) prepared in Example 1 was applied by a spinner onto a silicon substrate and pre-baked on a hot plate of 90° C. for 2 minutes to form a coating film. Then, the obtained coating film was irradiated with radiation ray by using a high pressure mercury lamp through a pattern mask having a predetermined line-and-space (10 to 1) pattern at an amount of exposure of 700 J/m², and developed in a 0.4 mass % aqueous solution of tetramethylammonium hydroxide at 25° C. for 60 seconds. The coating film was then post-baked in an oven at a curing temperature of 230° C. and a curing time of 30 minutes to form a patterned cured film. It was found that the space pattern in the line-and-space pattern of 3.0 μm had been completely dissolved in the obtained cured film, and thus advanced patterning was possible with a small amount of irradiation of radioactive ray of 1,000 J/m² or less. Consequently, it was found that Radiation-sensitive resin composition (β-I) prepared in Example 1 had excellent radiation sensitivity and the cured film formed by using the composition had an excellent patterning property.

### Example 5

Radiation-sensitive resin composition (β-II) prepared in Example 2 was applied by a spinner onto a silicon substrate and pre-baked on a hot plate of 90° C. for 2 minutes to form a coating film. Then, the obtained coating film was irradiated with radiation ray by using a high pressure mercury lamp through a pattern mask having a predetermined line-and-space (10 to 1) pattern at an amount of exposure of 1,000 J/m², and developed in a 0.4 mass % aqueous solution of tetramethylammonium hydroxide at 25° C. for 150 seconds. The coating film was then post-baked in an oven at a curing temperature of 230° C. and a curing time of 30 minutes to form a patterned cured film. It was found that the space pattern in the line-and-space pattern of 3.0 μm had been completely dissolved in the obtained cured film, and thus advanced patterning was possible with a small amount of irradiation of radioactive ray of 1,000 J/m² or less. Consequently, it was found that Radiation-sensitive resin composition (β-II) prepared in Example 2 had excellent radiation sensitivity and the cured film formed by using the composition had an excellent patterning property.

### Example 6

Radiation-sensitive resin composition (β-III) prepared in Example 3 was applied by a spinner onto a silicon substrate and pre-baked on a hot plate of 90° C. for 2 minutes to form a coating film. Then, the obtained coating film was irradiated with radiation ray by using a high pressure mercury lamp through a pattern mask having a predetermined line-and-space (10 to 1) pattern at an amount of exposure of 800 J/m², and developed in a 0.4 mass % aqueous solution of tetramethylammonium hydroxide at 25° C. for 80 seconds. The coating film was then post-baked in an oven at a curing temperature of 230° C. and a curing time of 30 minutes to form a patterned cured film. It was found that the space pattern in the line-and-space pattern of 3.0 μm had been completely dissolved in the obtained cured film, and thus advanced patterning was possible with a small amount of irradiation of radioactive ray of 1,000 J/m² or less. Consequently, it was found that Radiation-sensitive resin composition (β-III) prepared in Example 2 had excellent radiation sensitivity and the cured film formed by using the composition had an excellent patterning property.

### Formation of Cured Film and Evaluation of Resistance

### Example 7

### Cured Film Formed of Radiation-Sensitive Resin Composition (β-I)

Radiation-sensitive resin composition (β-I) prepared in Example 1 was applied by a spinner onto a non-alkali glass substrate and pre-baked on a hot plate of 90° C. for 2 minutes to form a coating film. Then, the obtained coating film was irradiated with radiation ray by using a high pressure mercury lamp at an amount of exposure of 700 J/m², and developed in a 0.4 mass % aqueous solution of tetramethylammonium hydroxide at 25° C. for 80 seconds. The coating film was then post-baked in an oven at a curing temperature of 230° C. and a curing time of 30 minutes to form a cured film.

### Example 8

### Cured Film Formed of Radiation-Sensitive Resin Composition (β-II)

Radiation-sensitive resin composition (β-II) prepared in Example 2 was applied by a spinner onto a non-alkali glass substrate and pre-baked on a hot plate of 90° C. for 2 minutes to form a coating film. Then, the obtained coating film was irradiated with radiation ray by using a high pressure mercury lamp at an amount of exposure of 1,000 J/m², and developed in a 0.4 mass % aqueous solution of tetramethylammonium hydroxide at 25° C. for 150 seconds. The coating film was then post-baked in an oven at a curing temperature of 230° C. and a curing time of 30 minutes to form a cured film.

### Example 9

### Cured Film Formed of Radiation-Sensitive Resin Composition (β-III)

Radiation-sensitive resin composition (β-III) prepared in Example 3 was applied by a spinner onto a non-alkali glass substrate and pre-baked on a hot plate of 90° C. for 2 minutes to form a coating film. Then, the obtained coating film was irradiated with radiation ray by using a high pressure mercury lamp at an amount of exposure of 800 J/m², and developed in a 0.4 mass % aqueous solution of tetramethylammonium hydroxide at 25° C. for 150 seconds. The coating film was then post-baked in an oven at a curing temperature of 230° C. and a curing time of 30 minutes to form a cured film.

### Example 10

### Evaluation of Heat-Resistance

The cured film by the forming method in Example 7 was further heated in an oven at 230° C. for 20 minutes, and the film thicknesses before and after the heating were each measured by a contact probe-type film thickness meter (ALPHASTEP IQ, KLA-Tencol). Furthermore, a film residual ratio (the film thickness after the treatment/the film thickness before the treatment×100) was calculated, and this film residual ratio was considered as heat-resistance. The film residual ratio was 99%, and thus the heat-resistance was judged as fine.

Similarly, the cured film by the forming method in Example 8 was further heated in an oven at 230° C. for 20 minutes, and the film thicknesses before and after the heating were each measured by a contact probe-type film thickness meter (ALPHASTEP IQ, KLA-Tencol). Furthermore, a film residual ratio (the film thickness after the treatment/the film thickness before the treatment×100) was calculated, and this film residual ratio was considered as heat-resistance. The film residual ratio was 99%, and thus the heat-resistance was judged as fine.

Similarly, the cured film by the forming method in Example 9 was further heated in an oven at 230° C. for 20 minutes, and the film thicknesses before and after the heating were each measured by a contact probe-type film thickness meter (ALPHASTEP IQ, KLA-Tencol). Furthermore, a film residual ratio (the film thickness after the treatment/the film thickness before the treatment×100) was calculated, and this film residual ratio was considered as heat-resistance. The film residual ratio was 99%, and thus the heat-resistance was judged as fine.

### Example 11

### Evaluation of Light Resistance

The cured film by the forming method in Example 7 was further irradiated with ultraviolet light of 800,000 J/m² at an irradiance of 130 mW by using an UV irradiation apparatus (UVX-02516S1JS01, Ushio Inc.), and the amount of decrease of the film after the irradiation was examined. The amount of decrease of the film was 2% or less, and thus the light resistance was judged as fine.

Similarly, the cured film by the forming method in Example 8 was further irradiated with ultraviolet light of 800,000 J/m² at an irradiance of 130 mW by using an UV irradiation apparatus (UVX-02516S1JS01, Ushio Inc.), and the amount of decrease of the film after the irradiation was examined. The amount of decrease of the film was 2% or less, and thus the light resistance was judged as fine.

Similarly, the cured film by the forming method in Example 9 was further irradiated with ultraviolet light of 800,000 J/m² at an irradiance of 130 mW by using an UV irradiation apparatus (UVX-02516S1JS01, Ushio Inc.), and the amount of decrease of the film after the irradiation was examined. The amount of decrease of the film was 2% or less, and thus the light resistance was judged as fine.

It was found from the above-mentioned results that Radiation-sensitive resin compositions (β-I) to (β-III) prepared in Examples 1 to 3 can be patterned at a high level, and that cured films obtained by using the compositions can be preferably used as protective films and banks for organic EL display elements.

As mentioned above, according to an embodiment of the present invention, an organic EL element having constitutional elements having desired shapes such as a bank and a protective film having desired shapes can be obtained.

Furthermore, according to another embodiment of the present invention, a radiation-sensitive resin composition that is used for forming a protective film having a desired shape for an organic EL element can be obtained.

Furthermore, according to another embodiment of the present invention, a radiation-sensitive resin composition that is used for forming a bank having a desired shape for an organic EL element can be obtained.

Furthermore, according to another embodiment of the present invention, a cured film that forms a protective film having a desired shape for an organic EL element can be obtained.

Furthermore, according to another embodiment of the present invention, a cured film that forms a bank having a desired shape for an organic EL element can be obtained.

The organic EL display element according to an embodiment of the present invention can increase the effective surface area of an organic luminescent layer in a pixel, and can form the organic luminescent layer with high producibility and high precision by utilizing an inkjet process or the like. Furthermore, the organic EL display element can decrease lowering in performances due to ultraviolet ray or impurities such as moisture. Therefore, this organic EL display element can be preferably used for large-sized flat television sets and the like for which excellent display quality and reliability are required.

What is claimed is:

1. An organic EL element comprising a substrate, an active element disposed on the substrate, a protective film covering the active element, a first electrode disposed on the protective film, an organic luminescent layer disposed on the first electrode, and a second electrode disposed on the organic luminescent layer,
wherein the protective film comprises a first resin, and at least one of a compound having a quinonediazide structure and a compound having an indenecarboxylic acid structure.

2. The organic EL element according to claim 1, wherein
the protective film has a through-hole, and
the first electrode is configured to be connected to the active element through the through-hole.

3. The organic EL element according to claim 1, wherein the first resin is formed of at least one kind selected from the group consisting of an acrylic resin having a carboxyl group, a polyimide resin, a polysiloxane and a novolak resin.

4. The organic EL element according to claim 1, wherein the protective film contains an ultraviolet absorber.

5. The organic EL element according to claim 4, wherein the ultraviolet absorber comprises one kind selected from a compound represented by the following general formula (1) and a compound represented by the following general formula (2): 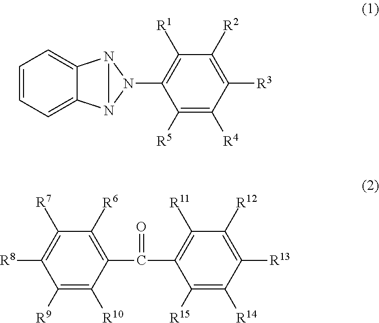
wherein in the formulas (1) and (2), R¹ to R¹⁵ each independently represents hydrogen, an alkyl group having 1 to 20 carbon atom(s), an alkoxy group having 1 to 20 carbon atom(s), a benzoyloxy group having 1 to 20 carbon atom(s) or a hydroxyl group.

6. The organic EL element according to claim 1, which comprises a bank disposed on the active element and configured to define an arranging area for the organic luminescent layer.

7. The organic EL element according to claim 6, wherein the bank comprises a second resin, and at least one of a compound having a quinonediazide structure and a compound having an indenecarboxylic acid structure.

8. The organic EL element according to claim 7, wherein the second resin is formed of at least one kind selected from the group consisting of an acrylic resin having a carboxyl group, a polyimide resin, a polysiloxane and a novolak resin.

9. The organic EL element according to claim 6, wherein the bank contains an ultraviolet absorber.

10. The organic EL element according to claim 9, wherein the ultraviolet absorber comprises one kind selected from a compound represented by the following general formula (1) and a compound represented by the following general formula (2): 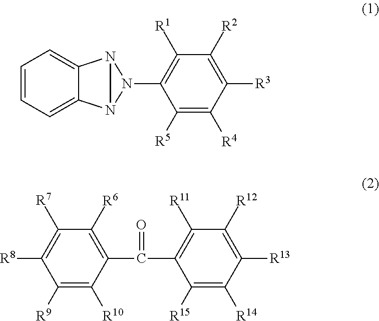
wherein in the formulas (1) and (2), R¹ to R¹⁵ each independently represents hydrogen, an alkyl group having 1 to 20 carbon atom(s), an alkoxy group having 1 to 20 carbon atom(s), a benzoyloxy group having 1 to 20 carbon atom(s) or a hydroxyl group.

11. The organic EL element according to claim 1, wherein the active element is configured to have a semiconductor layer, and the semiconductor layer is configured by using silicon (Si).

12. The organic EL element according to claim 1, wherein the active element is configured to have a semiconductor layer, and the semiconductor layer is formed by using an oxide configured to comprise at least one kind of indium (In), zinc (Zn) and tin (Sn).

13. The organic EL element according to claim 12, wherein the semiconductor layer is formed by using at least one kind of zinc oxide (ZnO), indium gallium zinc oxide (IGZO), zinc tin oxide (ZTO) and indium zinc oxide (IZO).

14. An organic EL element comprising a substrate, an active element disposed on the substrate, a first electrode connected to the active element, an organic luminescent layer disposed on the first electrode, a bank disposed on the active element and configured to define an arranging area for the organic luminescent layer, and a second electrode disposed on the organic luminescent layer,
wherein the bank comprises a resin, and at least one of a compound having a quinonediazide structure and a compound having an indenecarboxylic acid structure.

15. The organic EL element according to claim 14, wherein the resin is formed of at least one kind selected from the group consisting of an acrylic resin having a carboxyl group, a polyimide resin, a polysiloxane and a novolak resin.

16. The organic EL element according to claim 14, wherein the bank contains an ultraviolet absorber.

17. The organic EL element according to claim 16, wherein the ultraviolet absorber comprises one kind selected from a compound represented by the following general formula (1) and a compound represented by the following general formula (2): 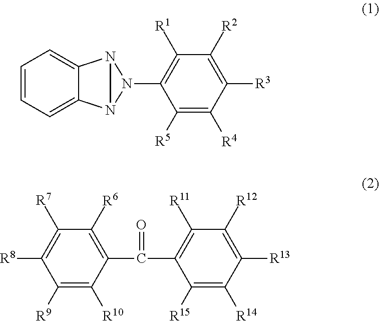
wherein in the formulas (1) and (2), R¹ to R¹⁵ each independently represents hydrogen, an alkyl group having 1 to 20 carbon atom(s), an alkoxy group having 1 to 20 carbon atom(s), a benzoyloxy group having 1 to 20 carbon atom(s) or a hydroxyl group.

18. The organic EL element according to claim 14, which comprises a protective film covering the active element on the active element, and the first electrode is disposed on the protective film and configured to be connected to the active element through a through-hole disposed on the protective film.

19. The organic EL element according to claim 14, wherein
the active element is configured to have a semiconductor layer, and
the semiconductor layer is configured by using silicon (Si).

20. The organic EL element according to claim 14, wherein
the active element is configured to have a semiconductor layer, and
the semiconductor layer is formed by using an oxide configured to comprise at least one kind of indium (In), zinc (Zn) and tin (Sn).

21. The organic EL element according to claim 20, wherein the semiconductor layer is formed by using at least one kind of zinc oxide (ZnO), indium gallium zinc oxide (IGZO), zinc tin oxide (ZTO) and indium zinc oxide (IZO).

22. A radiation-sensitive resin composition for use in the formation of the protective film of the organic EL element according to claim 1,
which comprises a resin and a compound having a quinonediazide structure.

23. A radiation-sensitive resin composition for use in the formation of the bank of the organic EL element according to claim 14,
which comprises a resin and a compound having a quinonediazide structure.

24. The radiation-sensitive resin composition according to claim 23, wherein the organic EL element is configured by the active element having a semiconductor layer, and the semiconductor layer is formed by using an oxide constituted by containing at least one of indium (In), zinc (Zn) and tin (Sn).

25. A cured film formed by using the radiation-sensitive resin composition according to claim 22, which constitutes a protective film for an organic EL element.

26. A cured film formed by using the radiation-sensitive resin composition according to claim 23, which constitutes a bank for an organic EL element.
